(19) United States
(12) Patent Application Publication
(10) Pub. No.: US 2025/0372357 A1
(43) Pub. Date: Dec. 4, 2025

(54) PARASITIC PLASMA SUPPRESSOR

(71) Applicant: Lam Research Corporation, Fremont, CA (US)

(72) Inventors: Yogesh Babbar, Hillsboro, OR (US); Sam Jafarian-Tehrani, Fremont, CA (US); David French, Fort Myers, FL (US); Yukinori Sakiyama, West Linn, OR (US); Weifeng Cheng, Portland, OR (US); Keith Joseph Martin, Tualatin, OR (US); Andrew H. Breninger, Newberg, OR (US); Curtis Warren Bailey, West Linn, OR (US)

(21) Appl. No.: 18/876,634

(22) PCT Filed: Jun. 28, 2023
(86) PCT No.: PCT/US2023/026435

§ 371 Date: Dec. 18, 2024

Related U.S. Application Data
(60) Provisional application No. 63/367,307, filed on Jun. 29, 2022.

(51) Int. Cl. H01J 37/32

(52) U.S. Cl. CPC H01J 37/32651; H01J 37/32642; H01J 2237/3321

(57) ABSTRACT

A parasitic plasma suppressor configured to suppress (or at least reduce) the generation of parasitic plasma outside an intended region, such as suppress the generation of parasitic plasma in areas adjacent a pedestal in a processing chamber of a plasma-enhanced processing system.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Some semiconductor processing systems may employ plasma when etching features into existing structures or depositing thin films on, for example, a substrate in a processing chamber. For instance, plasma-enhanced chemical vapor deposition (PECVD) is a type of plasma deposition used to deposit thin films from a gas state (e.g., vapor state) to a solid state on a substrate. In plasma etching, highly energetic and/or reactive species produced from one or more process gases may be caused to bombard and/or react with a surface to remove material therefrom, and, thereby, etch the surface. During deposition, one or more process gases may be delivered to the processing chamber using a showerhead arranged over the substrate. Power, such as radio frequency (RF) power, may be supplied to the showerhead or an electrode to generate plasma in a region proximate the substrate. Energetic electrons in the plasma ionize or dissociate reactant gases to generate more chemically reactive radicals, which react to form the thin film on the substrate. In this manner, the energy supplied by the plasma may be utilized to reduce process temperatures that would otherwise thermally fuel the reactions. It is noted, however, that reactant gas at other locations in the processing chamber may be excited to generate unwanted (or parasitic) plasma.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the disclosure.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

Some embodiments provide an apparatus capable of suppressing (or at least reducing) the generation of parasitic plasma outside an intended region, such as suppressing the generation of parasitic plasma in areas adjacent a pedestal in a processing chamber of a plasma-enhanced processing system.

Additional aspects will be set forth in the detailed description which follows, and, in part, will be apparent from the disclosure, or may be learned by practice of the disclosed embodiments and/or the claimed subject matter.

According to an embodiment, an apparatus configured to mitigate parasitic plasma generation in association with a plasma-enhanced process includes an annular shield structure. The annular shield structure includes a first inner surface, a first outer surface, a first upper surface, a first lower surface, and a plurality of openings. The first outer surface opposes the first inner surface in a radial direction. The first upper surface extends between the first inner surface and the first outer surface. The first lower surface extends between the first inner surface and the first outer surface. The first lower surface opposes the first upper surface in an axial direction transverse to the radial direction. The plurality of openings longitudinally extends between the first upper surface and the first lower surface. The openings respectively include a maximum dimension in a plane perpendicular to the axial direction that is less than or equal to about twice a plasma sheath thickness associated with the plasma-enhanced process.

In some embodiments, the maximum dimension may extend in the radial direction.

In some embodiments, the openings may respectively further include a minimum dimension in the axial direction or a direction transverse to the axial direction.

In some embodiments, the annular shield structure may include a plurality of annular shield rings spaced apart from one another by the maximum dimension in the radial direction such that the openings are defined by the spacing between the annular shield rings.

In some embodiments, the annular shield structure may be formed as a unitary body, and the openings may be defined as through-holes extending through the unitary body.

In some embodiments, the apparatus may further include an annular support structure. The annular support structure may include a second inner surface, and a second outer surface between the first inner surface and the second inner surface in the radial direction such that the annular shield structure surrounds the annular support structure. The annular shield structure and the annular support structure may be detachably coupled to one another.

In some embodiments, the annular shield structure and the annular support structure may be detachably coupled to one another via a bayonet-type engagement.

In some embodiments, the bayonet-type engagement may include a plurality of protrusions extending radially from one of the first inner surface and the second outer surface, and a plurality of slots defined in the other of the first inner surface and the second outer surface. The slots may be respectively configured to receive, in a first slot portion, a corresponding protrusion among the protrusions in response to relative translation between the annular shield structure and the annular support structure in the axial direction. The slots may also be respectively configured to receive, in a second slot portion communicatively coupled to the first slot portion, the corresponding protrusion in response to relative rotation between the annular shield structure and the annular support structure in a first rotational direction about an axis extending in the axial direction.

In some embodiments, the plurality of protrusions may include at least three protrusions.

In some embodiments, the plurality of protrusions may include at least four protrusions.

In some embodiments, the annular shield structure may include a plurality of annular shield rings spaced apart from one another by the maximum dimension in the radial direction such that the openings are defined by the spacing between the annular shield rings, and the annular shield rings may respectively include a corresponding set of the plurality of slots.

In some embodiments, upper surfaces of the respective annular shield rings may be offset from one another in the axial direction.

In some embodiments, the upper surfaces of the annular shield rings may be offset such that the upper surfaces of the annular shield rings increase in distance from a reference plane with increasing distance from the first inner surface. The reference plane may include an upper surface among the upper surfaces that is closest to the first inner surface.

In some embodiments, in an engaged state of the bayonet-type engagement, corresponding slots of the corresponding sets may be configured to receive a same corresponding protrusion among the plurality of protrusions.

In some embodiments, the apparatus may further include one or more retaining structures configured to constrain relative rotation between the annular shield structure and the annular support structure in a second rotational direction about the axis. The second rotational direction may be opposite the first rotational direction.

In some embodiments, at least one slot among the slots may be further configured to receive a retaining structure among the one or more retaining structures in the first slot portion of the at least one slot and a third slot portion of the at least one slot in response to relative translation between the retaining structure and the at least one slot in the radial direction. The third slot portion of the at least one slot may be communicatively coupled between the first slot portion of the at least one slot and the second slot portion of the at least one slot. Further, in an engaged stated state of the annular shield structure and the annular support structure and an engaged state of the retaining structure and the at least one slot, the retaining structure may be configured to retain the corresponding protrusion in the second slot portion of the at least one slot.

In some embodiments, the retraining structure may include a main body portion, a first protrusion extending from a first sidewall of the main body portion, and a plurality of second protrusions extending from a lower surface of the main body portion, the first protrusion, or the main body portion and the first protrusion. In the engaged state of the retaining structure and the at least one slot: the main body may be disposed in the first slot portion of the at least one slot, the first protrusion may be disposed in one or both of the second slot portion of the at least one slot and the third slot portion of the at least one slot, and the second protrusions may be disposed in respective openings among the openings in the annular shield structure.

In some embodiments, the apparatus may further include one or more retaining structures. At least one slot among the slots may be further configured to receive a retaining structure among the one or more retaining structures in the first slot portion of the at least one slot and a third slot portion of the at least one slot in response to relative translation between the retaining structure and the at least one slot in the radial direction. The third slot portion of the at least one slot may connect the first slot portion of the at least one slot to the second slot portion of the at least one slot. In an engaged stated state of the annular shield structure and the annular support structure and an engaged state of the retaining structure and the at least one slot, the retaining structure may be configured to retain the corresponding protrusion in the second slot portion of the at least one slot and may constrain relative rotation between the annular shield structure and the annular support structure in a second rotational direction about the axis. The second rotational direction may be opposite the first rotational direction.

In some embodiments, the annular support structure may further include at least one inner protrusion extending from the second inner surface towards a central axis of the annular support structure. The central axis may extend in the axial direction. The at least one inner protrusion may include a third upper surface, and a third lower surface opposing the third upper surface in the axial direction.

In some embodiments, the at least one inner protrusion may circumferentially extend about at least part of a periphery of the annular support structure.

In some embodiments, the apparatus may further include a process chamber and a pedestal. The process chamber may include at least one sidewall. The pedestal may be supported within the process chamber. The pedestal may include an outer boundary surface. In the radial direction, the annular shield structure may be disposed between the outer boundary surface of the pedestal and the at least one sidewall.

In some embodiments, the apparatus may further include a showerhead supported in the process chamber such that the showerhead faces the pedestal in the axial direction. The showerhead may be configured to distribute one or more process gases in a region overlying the pedestal.

In some embodiments, the apparatus may further include at least one dielectric ring surrounding the outer boundary surface of the pedestal. The at least one dielectric ring may include a fourth inner surface facing the outer boundary surface of the pedestal in the radial direction, a fourth outer surface opposing the fourth inner surface in the radial direction, a fourth upper surface extending between the fourth inner surface and the fourth outer surface, and a fourth lower surface extending between the fourth inner surface and the fourth outer surface. The fourth lower surface may oppose the fourth upper surface in the axial direction. In the radial direction, the annular shield structure may be disposed between the at least one dielectric ring and the at least one sidewall.

In some embodiments, the first inner surface may be spaced apart from the fourth outer surface by a dimension in the plane perpendicular to the axial direction that is less than or equal to about the plasma sheath thickness associated with the plasma-enhanced process.

In some embodiments, the apparatus may further include a focus ring disposed on an outer peripheral portion of an upper surface of the pedestal. The focus ring may include a fifth inner surface, a fifth outer surface opposing the fifth inner surface in the radial direction, a fifth upper surface extending between the fifth inner surface and the fifth outer surface, and a fifth lower surface extending between the fifth inner surface and the fifth outer surface. The fifth lower surface may oppose the fifth upper surface in the axial direction. In a plan view, at least a portion of the fourth upper surface may be adjacent to the fifth upper surface in the radial direction.

In some embodiments, the first upper surface may be disposed below a reference plane including the fifth upper surface.

In some embodiments, the fourth upper surface may be disposed at or below a reference plane including the fifth lower surface.

In some embodiments, the third lower surface may abut against the fourth upper surface.

In some embodiments, the second inner surface may abut against the fourth outer surface.

In some embodiments, the first outer surface may be spaced apart from the at least one sidewall.

In some embodiments, the plurality of protrusions may extend radially from the second outer surface, an outermost boundary surface of at least one of the plurality of protrusions may be disposed closer to the at least one sidewall than the first outer surface, and the outermost boundary surface of the at least one protrusion may be spaced apart from the at least one sidewall.

In some embodiments, the apparatus may further include a shroud lining an interior surface of the at least one sidewall. In the radial direction, the annular shield structure may be disposed between the outer boundary surface of the pedestal and the shroud. The outermost boundary surface of the at least one protrusion may be spaced apart from the shroud.

In some embodiments, the apparatus may further include a shroud lining an interior surface of the at least one sidewall. In the radial direction, the annular shield structure may be disposed between the outer boundary surface of the pedestal and the shroud.

In some embodiments, the shroud may include aluminum.

In some embodiments, the process chamber may include an exhaust gas port configured to evacuate gas in association with the plasma-enhanced process. The gas may include by-product gas, unreacted process gas, or by-product gas and unreacted process gas. The openings may be configured to permit the gas to flow from a first region overlying the pedestal to the exhaust gas port via a second region adjacent to the first region. The second region may be spaced apart from the pedestal in the radial direction. The openings may also be configured to suppress generation of plasma in the second region.

In some embodiments, in association with the plasma-enhanced process, the openings may be further configured to quench a flow of one or more energetic species therethrough.

In some embodiments, the pedestal may be configured to support a substrate in the process chamber. The substrate may include a maximum dimension in a direction perpendicular to the axial direction. A maximum dimension between opposing portions of the first inner surface in the direction perpendicular to the axial direction may be greater than the maximum dimension of the substrate.

In some embodiments, the first inner surface may abut against the second outer surface.

In some embodiments, a maximum dimension of the annular shield structure in the axial direction may be greater than a maximum dimension of the annular support structure in the axial direction.

In some embodiments, the annular shield structure may include a ceramic material.

In some embodiments, the annular support structure may include a ceramic material.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals refer to similar elements.

FIG. 1 schematically illustrates a substrate processing system, which may not only be used to process a wafer, but which is also capable of suppressing (or reducing) parasitic plasma according to some embodiments.

FIG. 2 schematically illustrates a partial cross-sectional view of the system of FIG. 1 according to some embodiments.

FIG. 3 schematically illustrates an enlarged view of a portion of FIG. 2 according to some embodiments.

FIG. 4 schematically illustrates a flow of one or more process gases in the system of FIG. 1 according to some embodiments.

FIG. 5A schematically illustrates a perspective view of an annular shield structure according to some embodiments.

FIG. 5B schematically illustrates a partial plan view of the annular shield structure of FIG. 5A according to some embodiments.

FIG. 6 schematically illustrates a partial side view of the annular shield structure of FIG. 5A according to some embodiments.

FIG. 7 schematically illustrates a plan view of a plurality of concentrically aligned annular shield rings according to some embodiments.

FIG. 8 schematically illustrates a plan view of an annular shield structure according to some embodiments.

FIGS. 9A and 9B schematically illustrate partial side views of the annular shield structure of FIG. 8 according to some embodiments.

FIG. 10 schematically illustrates a perspective view of an annular support structure according to some embodiments.

FIG. 11 schematically illustrates a bottom view of a portion of the annular support structure of FIG. 10 according to some embodiments.

FIG. 12 schematically illustrates a cross-sectional view of the annular support structure of FIG. 10 taken along sectional line 12-12 according to some embodiments.

FIG. 13A schematically illustrates a plan view of a portion of a partial assembly between an annular support structure and a plurality of annular shield rings according to some embodiments.

FIG. 13B schematically illustrates a plan view of a portion of an assembly between an annular support structure, a plurality of annular shield rings, and a retaining structure according to some embodiments.

FIG. 14 schematically illustrates a partial side view of the assembly of FIG. 13B according to some embodiments

FIG. 15 schematically illustrates a perspective view of a retaining structure according to some embodiments.

FIG. 16 schematically illustrates a partial side view of a partial assembly between two annular shield rings and a retaining structure according to some embodiments.

FIGS. 17A and 17B compare parasitic plasma generation in a conventional substrate processing system and a substrate processing system according to some embodiments.

FIG. 18 schematically illustrates a multi-station processing tool according to some embodiments.

### DETAILED DESCRIPTION OF SOME EMBODIMENTS

In the following description, numerous specific details are set forth in order to provide a thorough understanding of various embodiments. The disclosed embodiments may be practiced without some or all of these specific details. In other instances, well-known process operations have not been described in detail to not unnecessarily obscure the disclosed embodiments. While the disclosed embodiments will be described in conjunction with specific embodiments, it will be understood that it is not intended to limit the disclosed embodiments.

In this application, the terms “semiconductor wafer,” “wafer,” “substrate,” “wafer substrate” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. In addition to semiconductor wafers, other work pieces that may take advantage of the disclosed embodiments include various articles, such as printed circuit boards, magnetic recording media, magnetic recording sensors, mirrors, optical elements, micro-mechanical devices, and the like.

### Context

As previously mentioned, reactant gas at locations in a processing chamber other than a region overlying a process area (e.g., a deposition area, an etching area, etc.) on a substrate may be incidentally excited to generate parasitic plasma. The generation of parasitic plasma may not only reduce energy efficiencies associated with a plasma-enhanced process, such as PECVD of silicon nitride, but can cause a variety of other issues during plasma processing, such as particle contamination, spatial and temporal nonuniformity, thermal shock, premature failure of chamber components, electrical arcing, and/or the like. It is also recognized that the reduction in energy efficiency due, at least in part, to the generation of parasitic plasma can result in slower deposition or etching rates. Slower deposition and/or etching rates increase manufacturing time, and, as such, can increase manufacturing costs. Accordingly, various embodiments are directed towards parasitic plasma suppressors configured to prevent or at least reduce the generation of parasitic plasma, such as reduce the generation of parasitic plasma in areas adjacent a pedestal in a processing chamber. For instance, in some cases, a parasitic plasma suppressor may be configured to suppress the generation of parasitic plasma between a peripheral edge (or outer boundary surface) of a pedestal and an interior surface of a process chamber, such as an interior surface of a shroud (or liner) lining at least a portion of the process chamber. In this manner, various embodiments may enable less power to be diverted to surrounding areas in a process chamber, and, thereby, more power to be delivered to a region overlying a process area on a substrate. This increase in power may enable increased deposition and/or etching rates. Also, the suppression of parasitic plasma in unwanted areas adjacent to a pedestal may prevent (or at least reduce) particle contamination, spatial and temporal nonuniformity, thermal shock, premature failure of chamber components, electrical arcing, and/or the like, in association with a plasma-enhanced process.

### Systems for Parasitic Plasma Suppression

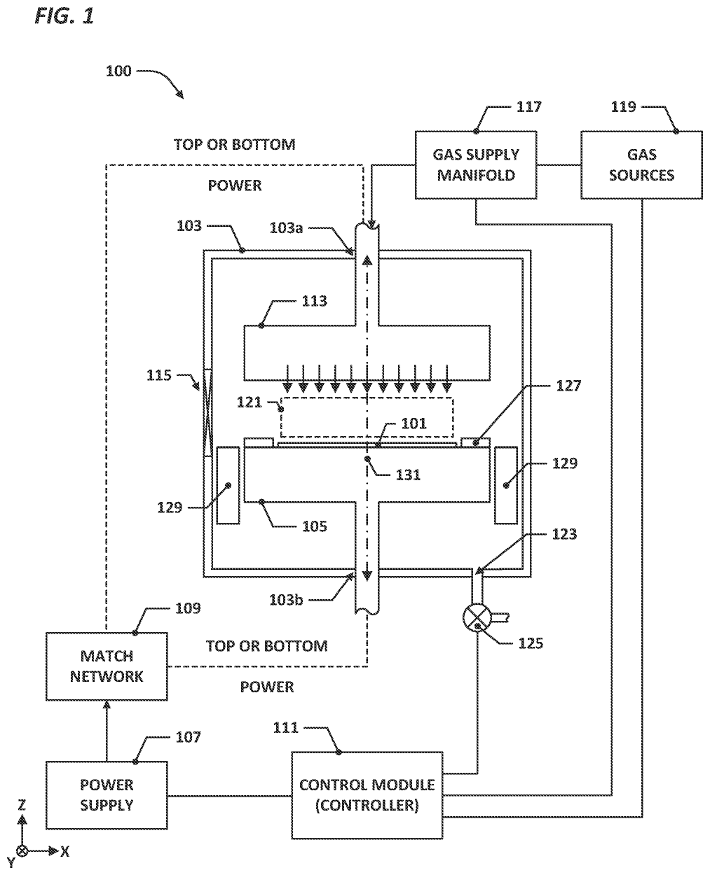

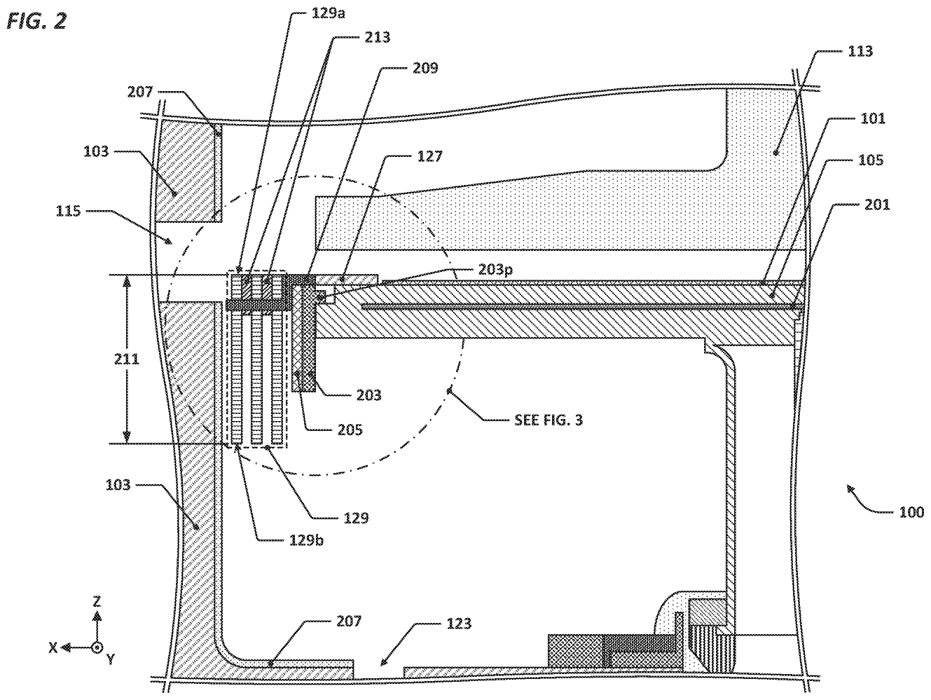

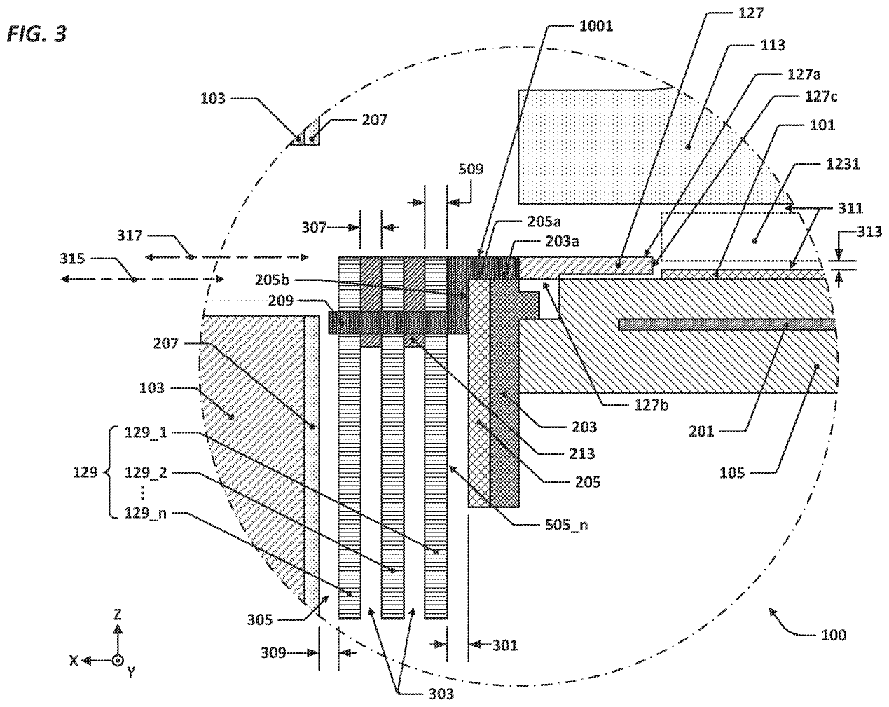

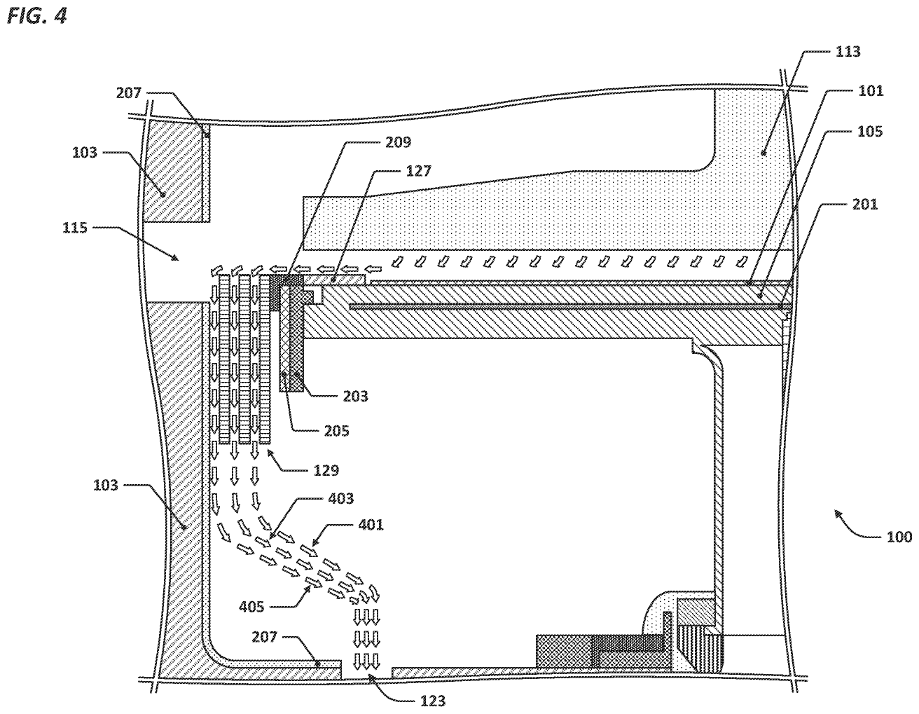

FIG. 1 schematically illustrates a substrate processing system (or system) 100, which may not only be used to process wafer 101, but may also be capable of suppressing (or reducing) parasitic plasma according to some embodiments. FIG. 2 schematically illustrates a partial cross-sectional view of the system of FIG. 1 according to some embodiments. FIG. 3 schematically illustrates an enlarged view of a portion of FIG. 2 according to some embodiments. FIG. 4 schematically illustrates a flow of one or more process gases in the system of FIG. 1 according to some embodiments.

System 100 includes chamber 103 that, in some instances, may be divided into an upper chamber portion and a lower chamber portion. A center column is configured to support a pedestal 105 when a surface of wafer 101 is being processed, e.g., when a film is being formed on the surface of wafer 101. In accordance with some embodiments, pedestal 105 may be or include a powered electrode, such as powered electrode 201. As such, pedestal 105 may be electrically coupled to power supply 107 via match network 109. To this end, power supply 107 may be controlled by control module (or controller) 111. In some embodiments, power may be provided to showerhead 113 instead of (or in addition to) pedestal 105. Control module 111 is configured to operate system 100 by executing one or more sequences of one or more instructions defining at least one process recipe. As such, control module 111 may set various operational inputs for defining a process recipe, such as power levels, timing parameters, process gases, mechanical movement of wafer 101, height of wafer 101 from pedestal 105, etc.

According to some embodiments, the center column may include a lift pin mechanism communicatively coupled to lift pins. The lift pin mechanism and, thereby, the lift pins may be controlled by a lift pin control signal from, for instance, control module 111. The lift pins may be used to raise wafer 101 from pedestal 105 to allow an end-effector to pick wafer 101 and to lower wafer 101 after being placed by the end end-effector. In some embodiments, the lift pins may be part of the center column. To this end, chamber 103 may include chamber transport port 115 through which the end-effector may introduce or remove wafer 101 from chamber 103. In some cases, relative displacement between pedestal 105 and showerhead 113 may be utilized to provide a controlled separation of wafer 101 from a surface of showerhead 113 facing wafer 101. Chamber 103 may also include openings 103a and 103b through which portions of pedestal 105 and showerhead 113 extend, such as stem portions of pedestal 105 and showerhead 113.

System 100 further includes gas supply manifold 117 fluidically connected to gas sources 119, e.g., gas chemistry supplies from a facility. Depending on the processing being performed, control module 111 may control the delivery of process gases from gas sources 119 to showerhead 113 via gas supply manifold 117. The process gases may be premixed or not. Appropriate valving and mass flow control mechanisms may be employed and controlled via control module 111 to ensure suitable process gases are delivered during deposition and plasma treatment phases of a process. In this manner, the chosen process gases may flow into showerhead 113 and may be distributed in processing region 121 defined between a surface of showerhead 113 facing wafer 101 and an upper surface of wafer 101. In some embodiments, wafer 101 may rest on a carrier ring, which may be supported on or by pedestal 105.

In various embodiments, process gases exit chamber 103 via exhaust gas port (or outlet) 123 fluidically coupled to, for instance, vacuum pump 125. Vacuum pump 125 may be a one or two stage mechanical dry pump and/or a turbomolecular pump. In this manner, process gases may be drawn out of chamber 103 to maintain a suitably low pressure therein. To this end, a closed-loop flow restriction device, such as a throttle valve or a pendulum valve, may be controlled via control module 111 to further ensure a suitably low pressure in chamber 103.

According to some embodiments, a carrier plate may be received over pedestal 105. The carrier plate may be configured to support and hold wafer 101, when received. In some implementations, the carrier plate may be a detachable unit (or structure) that can be moved into and out of chamber 103. For example, wafer 101 may be pre-loaded onto the carrier plate outside of chamber 103 and the carrier plate with wafer 101 loaded thereon may be transported into chamber 103. In this manner, the carrier plate with wafer 101 being loaded thereon may be received on pedestal 105. In some embodiments, the carrier plate may include a substrate support region defined in a central region and may extend a surface diameter of a top surface of pedestal 105. The surface diameter may be equal to (or about equal to) at least a diameter of wafer 101 received on the carrier plate.

Pedestal 105 may, in some implementations, be connected to an electrostatic chuck (ESC) control. A voltage applied through the ESC control to pedestal 105 enables generation of a clamping or a de-clamping force utilized to clamp or de-clamp the carrier plate to or from the upper surface of pedestal 105. In some embodiments, the voltage for clamping or de-clamping may be provided in response to a signal from control module 111. Further, control module 111 may also be configured to control the lift pin mechanism so that the carrier plate, and, thereby, wafer 101, may be lifted off the upper surface of pedestal 105 when the lift pins are activated.

As seen in FIGS. 1-3, focus ring 127 may be disposed on a periphery (or peripheral region) of pedestal 105, and may have upper surface 127a and lower surface 127b. In addition, focus ring 127 may be a quartz ring having inner surface 127c facing plasma generated in processing region (or area) 121. Although illustrated as rectangular area, processing region 121 may be more of a nebulous cloud-like region in which plasma may be generated. In some cases, focus ring 127 may be part of an assembly (or group of components) that surrounds pedestal 105. The assembly may include a plurality of dielectric rings, such as dielectric rings 203 and 205, which may be arranged below focus ring 127. In some implementations, dielectric rings 203 and 205 may be electrically floating.

Dielectric rings 203 and 205 may be formed of a ceramic material, such as alumina or aluminum nitride, but embodiments are not limited thereto. In some embodiments, dielectric rings 203 and 205 may be formed of the same material or different materials from one another. To this end, dielectric rings 203 and 205 may have respective annular shapes with corresponding interior diameters that are greater than an outer boundary of pedestal 105. Dielectric ring 205 may surround dielectric ring 203, and, thereby, may have a larger interior diameter than an exterior diameter of dielectric ring 203. Dielectric ring 203 may include protruded portion 203p configured to interface with pedestal 105, e.g., protruded portion 203p may be detachably coupled to pedestal 105. It is also noted that an exterior diameter of focus ring 127 may be smaller than the respective exterior diameters of dielectric rings 203 and 205. As such, one or more of upper surfaces 203a and 205a of dielectric rings 203 and 205 may be exposed from focus ring 127. For example, in a plan view, at least a portion of at least one of upper surfaces 203a and 205a of dielectric rings 203 and 205 may be adjacent to upper surface 127a of focus ring 127. Upper surfaces 203a and 205a of dielectric rings 203 and 205 may also be disposed at or below reference plane 315 including (e.g., tangent to) lower surface 127b of focus ring 127. As will become more apparent below, upper surfaces 203a and 205a of dielectric rings 203 and 205 may provide a mating (or resting) surface upon which one or more other components may be supported. Although dielectric rings 203 and 205 are depicted as abutting against one another, dielectric rings 203 and 205 may, in some embodiments, be spaced apart from one another. That being said, dielectric ring 205 may be coupled (e.g., detachably coupled) to dielectric ring 203 and/or pedestal 105. In some embodiments, one or more of dielectric rings 203 and/or 205 may be omitted.

System 100 may also include shroud (or liner) 207 lining one or more interior surfaces of chamber 103. Shroud 207 may be formed of a metal or metal alloy, such as aluminum or an aluminum alloy, but embodiments are not limited thereto. Shroud 207 is configured to be removed during servicing of chamber 103 to prevent (or at least reduce) build-up of material, e.g., metallic material, on the walls of chamber 103. To this end, shroud 207 may also be configured to reduce heat transfer to the walls of chamber 103 to help stabilize an internal temperature of chamber 103. As such, shroud 207 may serve as a sacrificial layer configured to prevent (or reduce) damage to chamber 103.

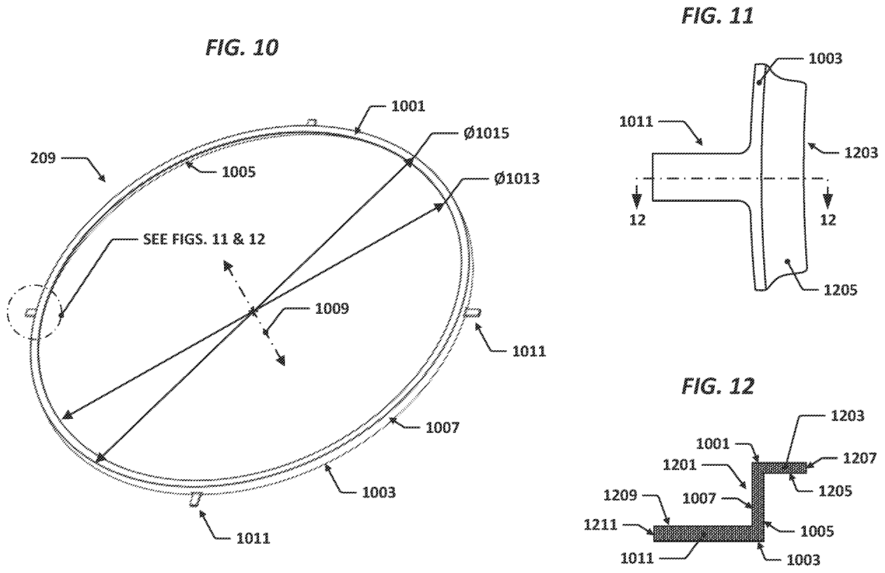

According to various embodiments, generation of parasitic plasma outside an area overlying an intended deposition or etching area on wafer 101, e.g., outside processing region 121, may be prevented or at least reduced via a parasitic plasma suppressor (or skirt), such as parasitic plasma suppressor 129. Hereinafter, parasitic plasma suppressor 129 will be referred to as suppressor 129. Suppressor 129 may be retro-fit into existing substrate processing systems and/or implemented as part of an initial substrate processing system installation. For instance, suppressor 129 may be supported from pedestal 105 via, for example, annular support structure 209. In some cases, annular support structure 209 may be supported by or from pedestal 105, such as supported from one or more shielding structures (e.g., one or both of dielectric rings 203 and 205), coupled to pedestal 105 or supported directly from pedestal 105 itself. An example annular support structure will be described in more detail in association with FIGS. 10-12. In some cases, suppressor 129 may be supported by or from chamber 103, shroud 207, and/or any other suitable structure in (or associated with) chamber 103.

Suppressor 129 is configured to suppress generation of parasitic plasma near RF powered, grounded, and/or floating surfaces (such as near pedestal 105, electrode 201 of pedestal 105, shroud 207, chamber 103, etc.) while enabling gases (e.g., process, by-product, unreacted, etc., gases) to flow from processing region 121 past pedestal 105, and, thereby, to be evacuated from chamber 103 via exhaust gas port 123, such as shown in FIG. 4. Thus, suppressor 129 may include a plurality of openings, e.g., openings 303, longitudinally extending between upper surface 129a and lower surface 129b of suppressor 129 to allow passage of the gases from processing region 121 to exhaust gas port 123 via, for instance, flow paths 401 and 403. As will become more apparent below, the configuration of openings 303 may be utilized to suppress generation of parasitic plasma in one or more regions arranged between pedestal 105 and surrounding chamber components, such as shroud 207. It is also noted that the gases from processing region 121 may flow to exhaust gas port 123 via gap (or choke point) 305 between suppressor 129 and shroud 207 lining one or more interior walls of chamber 103. This is shown in FIG. 4 via flow path 405. Some example suppressors will be described in more detail in association with at least FIGS. 2, 3, 5A, 5B, 6-8, 9A, and 9B. It, however, is generally noted that suppressor 129 may be formed of a plurality of annular shield rings, such as annular shield rings 129_1, 129_2, . . . , 129_n with “n” being a natural number greater than or equal to two. The plurality of annular shield rings may be spaced apart from one another (e.g., radially spaced apart from one another) to form openings 303. In some implementations, suppressor 129 may be formed as a unitary body with openings 303 being formed as passageways through the unitary body. Other embodiments, however, are also contemplated.

### Parasitic Plasma Suppressors

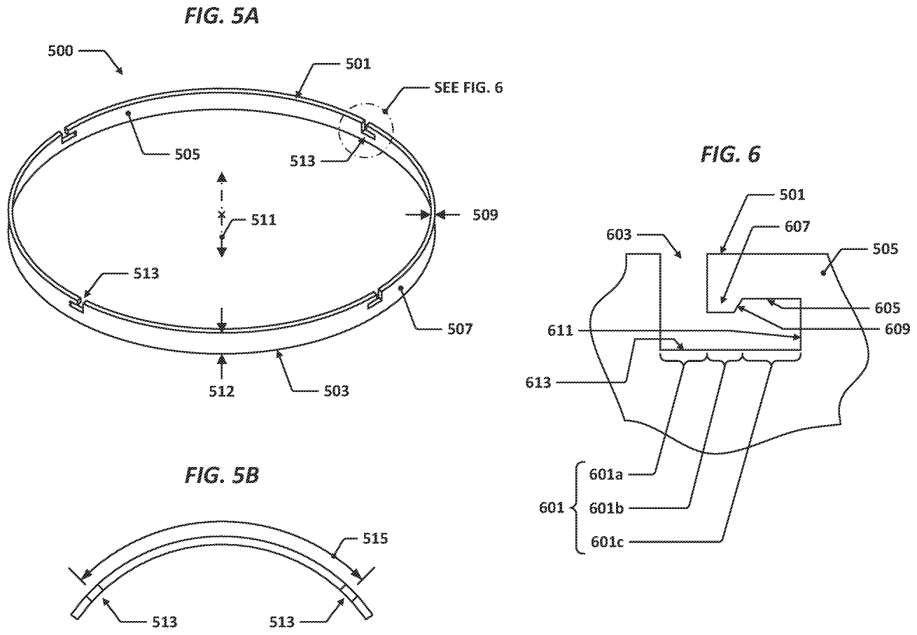

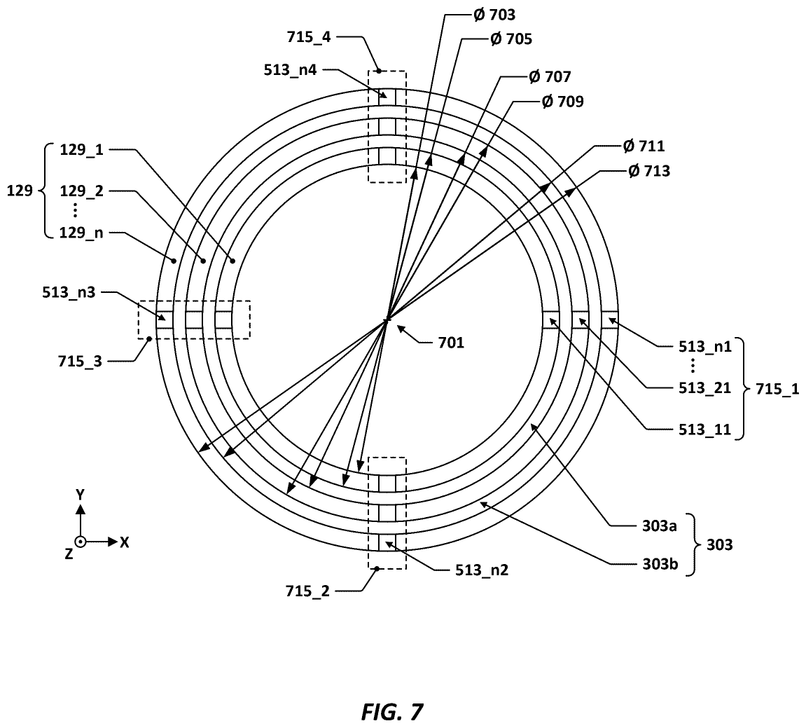

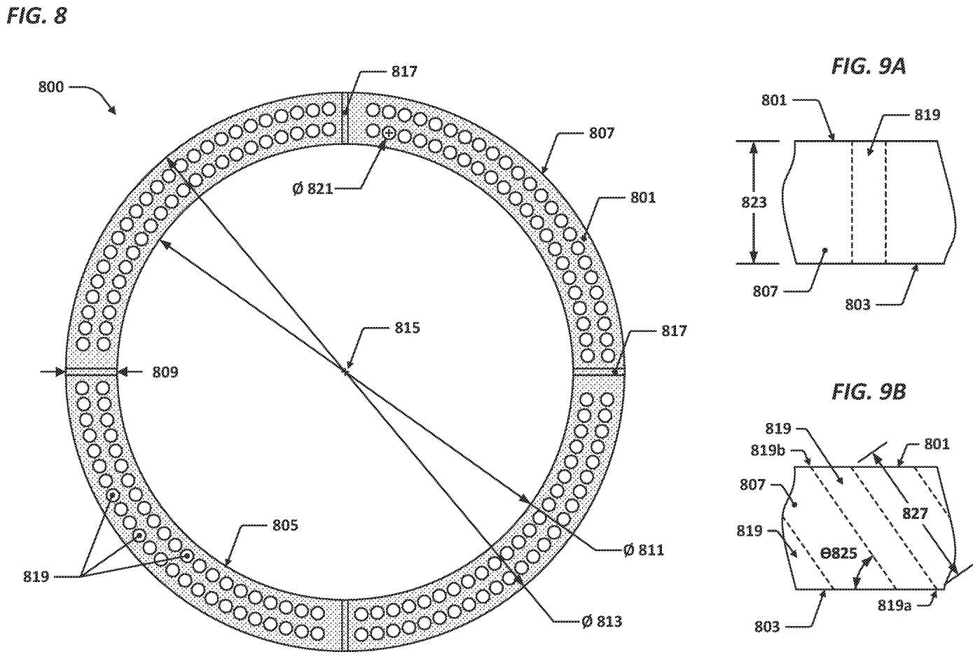

FIG. 5A schematically illustrates a perspective view of an annular shield ring according to some embodiments. FIG. 5B schematically illustrates a partial plan view of the annular shield structure of FIG. 5A according to some embodiments. FIG. 6 schematically illustrates a partial side view of the annular shield ring of FIG. 5A according to some embodiments. FIG. 7 schematically illustrates a plan view of a plurality of concentrically aligned annular shield rings according to some embodiments. FIG. 8 schematically illustrates a plan view of an annular shield structure according to some embodiments. FIGS. 9A and 9B schematically illustrates a partial side view of the annular shield structure of FIG. 8 according to some embodiments.

Referring to FIGS. 1, 2, 3, 5A, 5B, 6, and 7, suppressor 129 may be defined as (or by) an annular shield structure. The annular shield structure may include a plurality of annular shield rings, such as annular shield rings 129_1, 129_2, . . . , 129_n (where “n” is a natural number greater than or equal to two). In some cases, suppressor 129 may include three annular shield rings, but embodiments are not limited thereto. For instance, suppressor 129 may include two annular shield rings or more than three annular shield rings, such as four, five, six, seven, etc., annular shield rings. Annular shield rings 129_1, 129_2, . . . , 129_n may, in some embodiments, be formed of or include a dielectric material, such as a ceramic material, e.g., alumina or aluminum nitride, but embodiments are not limited thereto. In some instances, annular shield rings 129_1, 129_2, . . . , 129_n may be formed of a first material, such as a metal or metal alloy (e.g., aluminum or an aluminum alloy), and coated with a second material, such as a dielectric material. To this end, the material(s) of individual annular shield rings 129_1, 129_2, . . . , 129_n may be the same as or different from at least one other annular shield ring among annular shield rings 129_1, 129_2, . . . , 129_n.

According to some embodiments, annular shield rings 129_1, 129_2, . . . , 129_n may be concentrically aligned about axis 701, which may be a central axis extending in an axial direction parallel to, for example, a Z-axis direction (shown in FIG. 7 as extending out of the page). When supported from pedestal 105, axis 701 may be aligned (or substantially aligned) with or correspond to axis 131 in FIG. 1. As such, axis 131 may be a central axis extending in an axial direction parallel to, for example, the Z-axis direction shown in FIG. 1. Apart from having different dimensions, annular shield rings 129_1, 129_2, . . . , 129_n may be similarly configured, but embodiments are not limited thereto. Some example annular shield rings will be described in more detail in association with FIGS. 5A, 5B, 6, and 7.

Referring to FIGS. 5A, 5B, 6, and 7, as well as continued reference to FIGS. 1-3, annular shield ring 500 includes upper surface 501, lower surface 503, inner surface 505, and outer surface 507. Width 509 of annular shield ring 500 may extend between inner surface 505 and outer surface 507 in a radial direction, which may extend perpendicular to central axis 511. Length 512 of annular shield ring 500 may extend between upper surface 501 and lower surface 503 in an axial direction, which may extend parallel to central axis 511. In an assembled configuration of system 100, central axis 511 may be coincident (or substantially coincident) with axis 131. In some cases, annular shield ring 500 includes a plurality of engagement features, such as bayonet-type engagement features 513, but embodiments are not limited thereto. For example, the engagement features of annular shield ring 500 may be provided as through-holes, threaded through-holes, blind bores, threaded blind bores, protrusions, pins, hooks, bolts, screws, studs, anchors, etc. It is also contemplated that a mix of two or more different types of engagement features may be utilized in association with annular shield ring 500. For convenience, the engagement features of annular shield ring 500 will, hereinafter, be assumed to be of the same type and described as bayonet-type engagement features 513.

As seen in FIG. 5A, annular shield ring 500 includes four bayonet-type engagement features 513, two of which are identified, but embodiments are not limited thereto. For instance, annular shield ring 500 may include less than four bayonet-type engagement features, such as three bayonet-type engagement features, or may include greater than four bayonet-type engagement features, such as five, six, etc., bayonet-type engagement features. According to some embodiments, bayonet-type engagement features 513 may be circumferentially spaced apart from one another by angular pitch 515, which may be determined according to Eq. 1. For instance, as seen in FIG. 5A, annular shield ring 500 includes four bayonet-type engagement features 513, and, as such, angular pitch 515 may be (or may be about) 90°, but embodiments are not limited thereto. For instance, any suitable circumferential spacing of bayonet-type engagement features 513 may be utilized.

$$A = \frac{360 °}{n} \qquad Eq . 1$$

where:
   A=Angular pitch between adjacent bayonet-type engagement features 513
   n=Total number of bayonet-type engagement features 513 of annular shield ring 500

As will become more apparent below, bayonet-type engagement features 513 are configured to interface (or engage) with corresponding mating features of annular support structure 209. The engagement between the bayonet-type engagement features of annular shield rings 129_1, 129_2, . . . , 129_n and the corresponding mating features of annular support structure 209 may support annular shield rings 129_1, 129_2, . . . , 129_n about an outer boundary of pedestal 105 in chamber 103, and, as such, at least constrain displacement of suppressor 129 along axis 131. In some embodiments, annular support structure 209 may be omitted and bayonet-type engagement features 513 may interface with corresponding mating features of chamber 103, pedestal 105, dielectric ring 203, dielectric ring 205, and/or any other suitable component of system 100.

Referring to FIG. 6, bayonet-type engagement feature 513 may be defined as slot 601 extending through annular shield ring 500. Slot 601 may be configured as a J-slot (such as depicted in FIG. 6), but embodiments are not limited thereto. As such, slot 601 may have any suitable geometric configuration. In some embodiments, slot 601 may include first portion 601a, second portion 601b, and third portion 601c. First portion 601a may include opening 603 in upper surface 501. Third portion 601c may include mating (or resting) surface 605. Second portion 601b may extend between and communicatively couple third portion 601c and first portion 601a. In some embodiments, second portion 601b may include protruded portion 607 having impinging surface 609, and third portion 601c may include distal surface 611. Further, in some embodiments, first portion 601a, second portion 601b, and third portion 601c may share bottom surface 613.

Adverting to FIG. 7, annular shield rings 129_1, 129_2, . . . , 129_n have inner and outer diameters. For example, annular shield ring 129_1 has inner diameter 703 and outer diameter 705, annular shield ring 129_2 has inner diameter 707 and outer diameter 709, and annular shield ring 129_n has inner diameter 711 and outer diameter 713. As shown, outer diameter 713 is greater than inner diameter 711, which is greater than outer diameter 709. Outer diameter 709 is greater than inner diameter 707, which is greater than outer diameter 705. In addition, outer diameter 705 is greater than inner diameter 703, which is greater than a maximum dimension (e.g., outer diameter) of an adjacent component, such as dielectric ring 205, dielectric ring 203, or pedestal 105. It is at least apparent that inner diameter 703 and the maximum dimension of the adjacent component, e.g., dielectric ring 205, may be greater than a maximum dimension (e.g., diameter) of wafer 101. In some implementations, inner surface 505_n of annular shield ring 129_n may be spaced apart from an outer surface of the adjacent component, e.g., outer surface 205b of dielectric ring 205, by dimension 301, which may extend in a radial direction, e.g., in a direction parallel to the X-axis direction shown in FIG. 3.

As previously alluded, openings 303 may be defined by the spacing between adjacent annular shield rings, such as the spacing between annular shield ring 129_1 and annular shield ring 129_2 and the spacing between annular shield ring 129_2 and annular shield ring 129_n. In this manner, maximum dimensions (e.g., radial widths) of openings 303 may be defined by (or about) half the respective differences between the inner and outer diameters of adjacent annular shield rings. For instance, a first maximum dimension of first opening 303a between annular shield ring 129_1 and annular shield ring 129_2 may be equivalent (or substantially equivalent) to about half the difference between inner diameter 707 and outer diameter 705. A second maximum dimension of second opening 303b between annular shield ring 129_2 and annular shield ring 129_n may be equivalent (or substantially equivalent) to about half the difference between inner diameter 711 and outer diameter 709. In some embodiments, the first and second maximum dimensions may be equivalent (or substantially equivalent) to one another, but embodiments are not limited thereto. For descriptive convenience, it will be assumed that the first and second maximum dimensions are equivalent to one another and will be referred to as maximum dimension 307 (see FIG. 3). It is also noted that maximum dimension 307 may be greater than or equal to about maximum dimension 309 (see FIG. 3) in the radial direction between an outer boundary of suppressor 129 and an inner surface of shroud 207 or chamber 103. It is also contemplated that maximum dimension 307 may be greater than or equal to about dimension 301.

According to various embodiments, maximum dimensions 307 and 309 may not only be configured to allow sufficient flow rates (or flow conductance) of gas from processing region 121 to exhaust gas port 123, but may also be configured to suppress generation of parasitic plasma in one or more regions between pedestal 105 and surrounding components, such as chamber 103 and/or shroud 207. For instance, during a plasma-enhanced process implemented via system 100, chamber 103 may form a vacuum enclosure defining, at least in part, processing region 121. To this end, showerhead 113 may be utilized to provide one or more process gases (hereinafter, referred to as “process gases”) to processing region 121 overlying wafer 101 supported via pedestal 105. The process gases may be heated and/or supplied with energy, such as RF energy from an electric field generated between pedestal 105 and showerhead 113, that causes, at least in part, molecules of the process gases to disassociate and form plasma in processing region 121. With these conditions, electrons, ions, excited neutral atoms, and molecules may be formed in the discharge and/or during electron bombardment with a solid surface. As such, some secondary particles including, for example, photons, electrons, atoms, and ions may be generated. These species carry out energy from processing region 121 in various forms, such as kinetic, electrical, and/or chemical forms, and induce modification and restructuring due to their acceleration in a transition region between the unperturbed plasma of processing region 121 and an adjacent surface, such as an upper surface of wafer 101. This transition region is plasma sheath 311, which builds a net charge to balance an opposite charge on adjacent surfaces to the unperturbed plasma of processing region 121. In this manner, plasma sheath 311 maintains global current balance in such a way that, if sufficient space is not provided for the formation of plasma sheath 311, plasma typically cannot be formed or maintained in processing region 121. This general concept may be applied to the structural configuration of openings 303 of suppressor 129 and gap 305. For example, dimension 301 and maximum dimensions 307 and 309 may be configured so that a plasma sheath is unlikely to form near openings 303, annular shield rings 129_1, 129_2, . . . , 129_n, shroud 207, and/or interior walls of chamber 103.

According to various embodiments, dimension 301, maximum dimension 307 of openings 303, and maximum dimension 309 of gap 305 in a radial direction, e.g., in a direction parallel to the X-axis direction shown in FIG. 3, may be a multiple of sheath thickness 313 of plasma sheath 311. Sheath thickness 313 may, in some embodiments, be between about 1 mm and about 3 mm, such as between about 1 mm and about 1.5 mm, for instance, between about 2.5 mm and about 3 mm, e.g., between about 1.25 mm and about 2.75 mm. It is also contemplated that dimension 301, maximum dimension 307, and/or maximum dimension 309 may be sized less than sheath thickness 313 so long as a sufficient flow rate (or flow conductance) of gas from processing region 121 to exhaust gas port 123 may be realized.

As previously indicated, plasma sheath 311 is a layer having a greater density of positive ions and neutrals that balances an opposite negative charge on a surface of a material adjacent to plasma in processing region 121. In this way, light emission from plasma sheath 311 may be less intense than plasma in processing region 121 since fewer electrons are present, and, hence, few excitation-relaxation collisions occur. As such, plasma sheath 311 may be viewed as a dark boundary region (or space), which forms a potential barrier to prevent or reduce electrons from diffusing out of plasma in processing region 121. In some instances, one or more of maximum dimensions 307 and 309 in the radial direction may be less than or equal to about twice sheath thickness 313, but embodiments are not limited thereto. In some cases, maximum dimension 309 may be less than or equal to about maximum dimension 307. Also, dimension 301 may be equivalent (or substantially equivalent) to one half of sheath thickness 313, but embodiments are not limited thereto. With such a configuration, sufficient space is unlikely to be available for the formation of a plasma sheath near openings 303, annular shield rings 129_1, 129_2, . . . , 129_n, shroud 207, and/or interior walls of chamber 103. It is noted, however, that sheath thickness 313 will be dependent on the various processing conditions of system 100, such as temperature, pressure, RF power, RF frequency, width of processing region 121, etc. Accordingly, sheath thickness 313 may be fairly approximated according to the Debye length associated with the plasma-enhanced process employed via system 100. The Debye length may be fairly approximated via Eq. 2.

$${λ}_{D} = \sqrt{\frac{{ε}_{0} {k}_{B} / {q}_{e}^{2}}{{n}_{e} / {T}_{e} + {\sum }_{ij} {j}^{2} {n}_{ij} / {T}_{i}}} \qquad Eq . 2$$

where:
   λ_{D}=Debye length
   ε₀=permittivity of free space
   k_{B}=Boltzmann's constant
   qₑ=charge of an electron
   Tₑ=temperature of electrons
   Tᵢ=temperature of ions
   nₑ=density of electrons
   nᵢⱼ=density of atomic species i, with positive ionic charge jqₑ

Furthermore, openings 303 may have respective minimum dimensions extending in an axial direction, e.g., in a direction parallel to the Z-axis direction in FIG. 2. As with the respective maximum dimensions of openings 303 extending in a radial direction, first and second minimum dimensions of openings 303a and 303b in the axial direction may be equivalent (or substantially equivalent) to one another, but embodiments are not limited thereto. For descriptive convenience, it will be assumed that the first and second minimum dimensions are equivalent to one another and will be referred to as minimum dimension 211 shown in FIG. 2. Minimum dimension 211 of openings 303 may be configured to promote the energy depletion of radical (or energized) species that escape processing region 121. For example, by appropriately sizing minimum dimension 211 in the axial direction, a sufficient number of collisions are likely to occur as the radical species traverse the flow paths provided by openings 303. These collisions progressively deenergize (or quench) the radical species to mitigate the ability of plasma to survive near openings 303, annular shield rings 129_1, 129_2, . . . 129_n, shroud 207, and/or chamber 103. The same may also be true with respect to the flow path provided via gap 305.

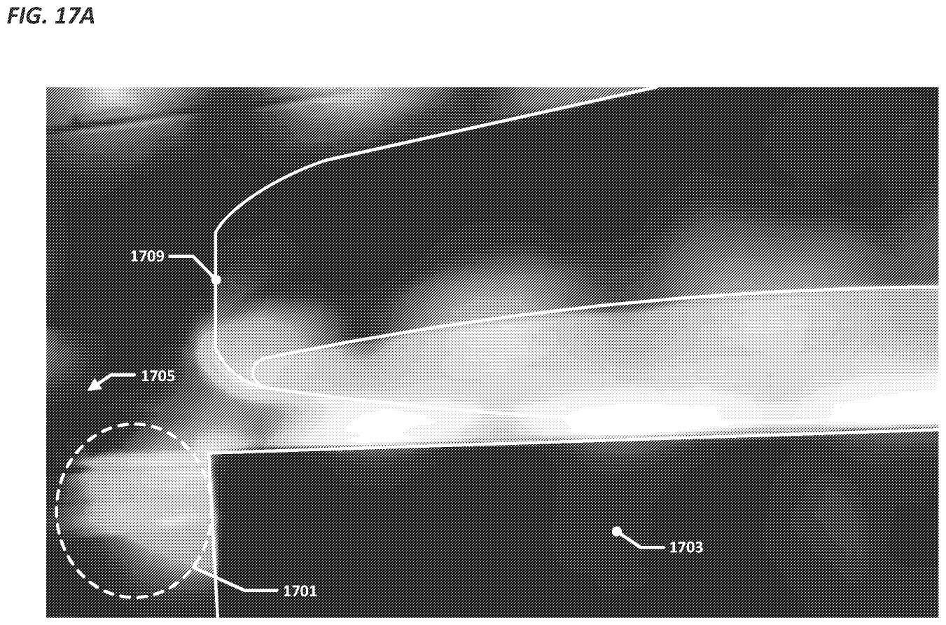

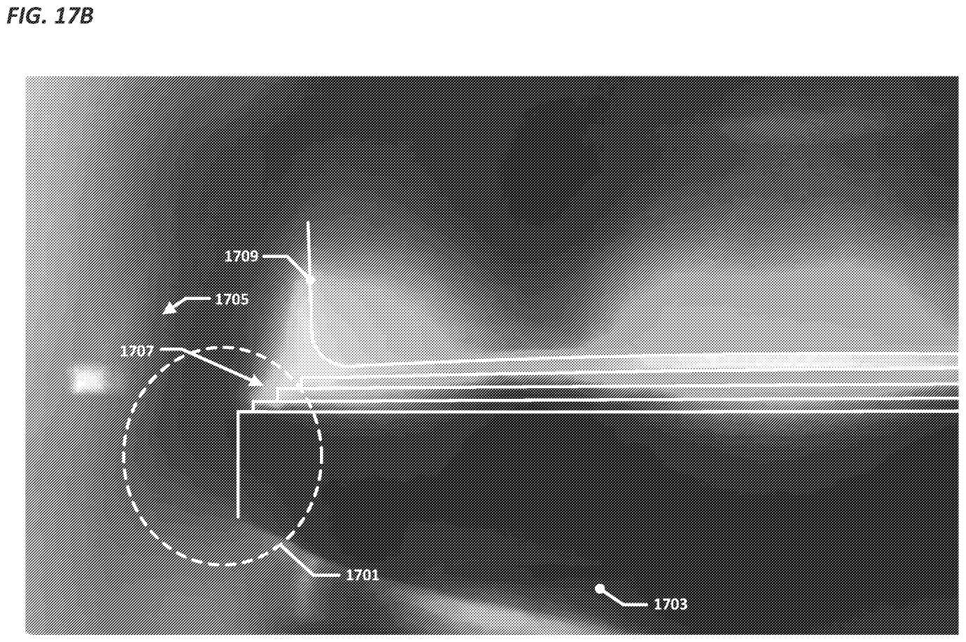

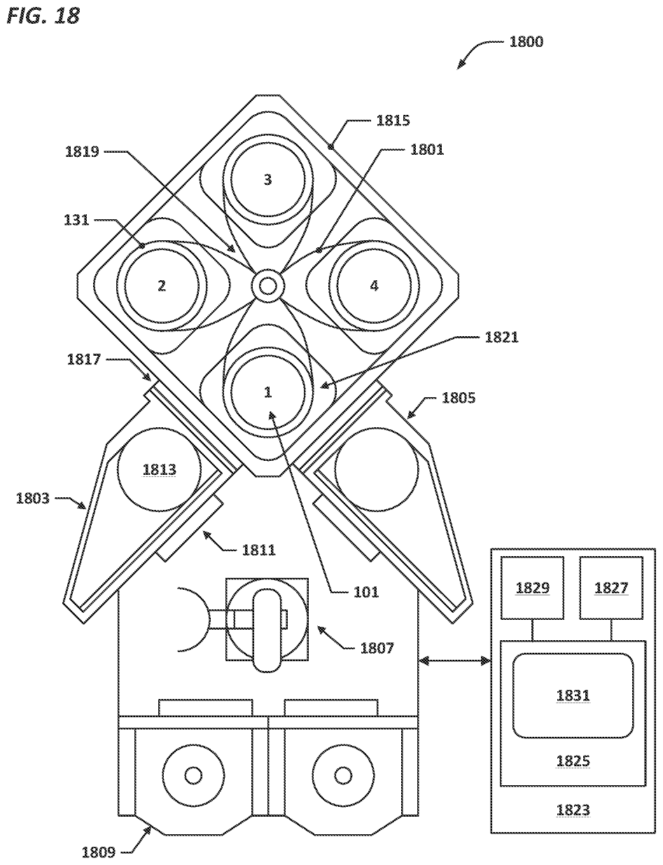

Although upper surface 129a of suppressor 129 (and, thereby, respective upper surfaces 501 of annular shield rings 129_1, 129_2, . . . , 129_n) are shown in FIGS. 2 and 3 as being co-planar with reference plane 317 including (e.g., tangent to) upper surface 127a of focus ring 127, embodiments are not limited thereto. For instance, upper surface 129a of suppressor 129 may be disposed axially above or below reference plane 317. In some embodiments, respective upper surfaces 501 of annular shield rings 129_1, 129_2, . . . , 129_n may be progressively offset from reference plane 317 with increasing radial distance from axis 131, e.g., with increasing radial distance from pedestal 105. For example, annular shield ring 129_n may be disposed axially closer to reference plane 317 than annular shield ring 129_2 which may be disposed axially closer to reference plane 317 than annular shield ring 129_1. Such an embodiment is shown in FIG. 17B. It is also contemplated that the opposite may be true. For example, annular shield ring 129_n may be disposed axially further from reference plane 317 than annular shield ring 129_2 which may be disposed axially further from reference plane 317 than annular shield ring 129_1. In some implementations, an arbitrary axial offset may exist between upper surfaces 501 of adjacent annular shield rings among annular shield rings 129_1, 129_2, . . . , 129_n. Further, although annular shield rings 129_1, 129_2, . . . , 129_n are shown having equivalent lengths 512 (see FIGS. 3 and 5A) extending in an axial direction, which may be parallel to the Z-axis direction in FIG. 3, embodiments are not limited thereto. In some implementations, respective lengths 512 of annular shield rings 129_1, 129_2, . . . , 129_n may be different from one another. According to some embodiments, differences between the respective lengths 512 of annular shield rings 129_1, 129_2, . . . , 129_n may be arbitrary.

Although annular shield rings 129_1, 129_2, . . . , 129_n have been described as being separate structures, it is also contemplated that annular shield rings 129_1, 129_2, . . . , 129_n may form features of a monolithic structure. For instance, one or more additive manufacturing techniques may be utilized to form annular shield rings 129_1, 129_2, . . . , 129_n as a single body (or piece). In this manner, one or more connecting portions may be formed on and/or between annular shield rings 129_1, 129_2, . . . , 129_n as the monolithic structure is being manufactured. For instance, the one or more connecting portions may extend radially between adjacent annular shield rings among annular shield rings 129_1, 129_2, . . . , 129_n, but embodiments are not limited thereto. In some instances, the monolithic structure may be additively manufactured via direct laser ceramic sintering. As another example, the monolithic structure may be formed using direct laser metal sintering, and, in some cases, coated with a dielectric material, such as ceramic. It is also contemplated that the monolithic structure may be machined from solid stock, such as billet material, and, in some implementations, coated with another material, such as a dielectric material.

In some embodiments, parasitic plasma suppressor 129 may be configured as a single annular shield structure (or “structure”) 800, such as shown in FIGS. 8 and 9A, versus being formed of a plurality of annular shield rings, such as annular shield rings 129_1, 129_2, . . . , 129_n. Structure 800 includes upper surface 801, lower surface 803, inner surface 805, and outer surface 807. Width 809 of structure 800 in a radial direction may extend between inner surface 805 having inner diameter 811 and outer surface 807 having outer diameter 813. The radial direction extends perpendicular to central axis 815, which is shown in FIG. 8 as extending into the page. Width 809 may correspond to half the difference between inner diameter 811 and outer diameter 813.

Similar to annular shield ring 500, structure 800 includes a plurality of bayonet-type engagement features, such as bayonet-type engagement features 817, which may interface with corresponding mating features of annular support structure 209. In this manner, bayonet-type engagement features 817 may be structurally similar to bayonet-type engagement features 513 at least described in association with FIGS. 5A, 5B, and 6. As seen in FIG. 8, structure 800 includes four bayonet-type engagement features 817, two of which are identified, but embodiments are not limited thereto. For instance, structure 800 may include less than four bayonet-type engagement features, such as three bayonet-type engagement features, or may include greater than four bayonet-type engagement features, such as five, six, seven, etc., bayonet-type engagement features.

According to various embodiments, structure 800 includes a plurality of openings, such as openings 819, longitudinally extending between upper surface 801 and lower surface 803. Openings 819 may not only be configured to allow a sufficient flow rate (or flow conductance) of gases from processing region 121 to exhaust gas port 123, but may also be configured to suppress generation of parasitic plasma in one or more regions arranged between pedestal 105 and surrounding components, such as chamber 103, shroud 207, etc. In this manner, openings 819 may correspond to openings 303 depicted in FIGS. 2 and 3. As such, openings 819 may have maximum dimension (e.g., maximum diameter) 821, which may be sized similarly to maximum dimension 307 to reduce the likelihood that sufficient space is available for formation of a plasma sheath (and, thereby, parasitic plasma) near openings 819, structure 800, shroud 207, and/or chamber 103. Moreover, openings 819 may have minimum dimension 823 in an axial direction extending parallel to central axis 815, such as illustrated in FIG. 9A. Minimum dimension 823 may be sized similarly to minimum dimension 211 to promote the energy depletion of radical species that escape processing region 121 and traverse at least one flow path provided via openings 819 on way to exhaust gas port 123.

In some embodiments, openings 819 may be axially inclined/declined at angle 825 relative lower and upper surfaces 803 and 801 of structure 800 such that respective leading edges 819a of openings 819 are circumferentially offset from corresponding trailing edges 819b of openings 819, such as depicted in FIG. 9B. In this manner, adjacent openings 819 may at least partially overlap one another in the axial direction, but embodiments are not limited thereto. Whether or not openings 819 at least partially overlap one another in the axial direction, the respective path lengths of openings 819 may be increased to minimum dimension 827 without increasing the thickness of structure 800 in the axial direction. It is also contemplated that axially inclining/declining openings 819 at angle 825 may enable the respective path lengths of openings 819 to remain as minimum dimension 823, but enable the thickness of structure 800 in the axial direction to be reduced. In some implementations, openings 819 may be radially inclined/declined or both radially and axially inclined/declined with respect to lower and upper surfaces 803 and 801 of structure 800. Whatever the case, minimum dimension 827 may at least be sized similarly to minimum dimension 211 to promote the energy depletion of radical species that escape processing region 121 and traverse at least one flow path provided by openings 819 on way to exhaust gas port 123.

Although openings 819 are shown having a circular cross-section in a plan view, embodiments are not limited thereto. For instance, openings 819 may have any suitable cross-sectional configuration, such as an oval, elliptical, triangular, quadrilateral, etc., cross-sectional configuration. In some implementations, openings 819 may have an egg-shaped or free-form cross-sectional configuration in a plan view. In any event, a maximum dimension in a plane perpendicular to central axis 815 of such openings may still correspond to maximum dimension 821 and a minimum dimension in the axial direction may still correspond to minimum dimension 823 or 827. That said, the maximum dimension in the plane perpendicular to central axis 815 of such alternatively configured openings may or may not extend in the radial direction relative to central axis 815.

### Support Structure

As previously mentioned, suppressor 129 may, in some implementations, be supported in chamber 103 from pedestal 105 via annular support structure 209. FIG. 10 schematically illustrates a perspective view of an annular support structure according to some embodiments. FIG. 11 schematically illustrates a bottom view of a portion of the annular support structure of FIG. 10 according to some embodiments. FIG. 12 schematically illustrates a cross-sectional view of the annular support structure of FIG. 10 taken along sectional line 12-12 according to some embodiments.

Referring to FIGS. 10-12, annular support structure 209 includes upper surface 1001, lower surface 1003, inner surface 1005, and outer surface 1007. Together, upper surface 1001, lower surface 1003, inner surface 1005, and outer surface 1007 define main body 1201. Main body 1201 includes inner protrusion 1203. In some cases, inner protrusion 1203 extends circumferentially inwards from inner surface 1005 towards central axis 1009. As such, inner protrusion 1203 may extend about an entire circumference of inner surface 1005, but embodiments are not limited thereto. For example, in some cases, inner protrusion 1203 may be divided into a plurality of inner protrusions circumferentially spaced apart from one another about central axis 1009. Inner protrusion 1203 may include mating (or resting) surface 1205 that, in some implementations, is configured to abut against one or both of upper surfaces 203a and 205a of dielectric rings 203 and 205 when annular support structure 209 is supported from pedestal 105. As seen in FIGS. 2 and 3, mating surface 1205 abuts against both of upper surfaces 203a and 205a of dielectric rings 203 and 205. It is also noted that when annular support structure 209 is supported from pedestal 105, inner surface 1005 may abut against outer surface 205b of dielectric ring 205 as shown in FIG. 3, but embodiments are not limited thereto. In those instances when both of dielectric rings 203 and 205 are omitted, mating surface 1205 and inner surface 1005 may abut against corresponding surfaces of pedestal 105, but embodiments are not limited thereto.

According to various embodiments, main body 1201 may have inner dimension (e.g., inner diameter) 1013 that is greater than or equal to an outer bounding dimension of dielectric ring 205. Further, main body 1201 may have an outer dimension (e.g., outer diameter) 1015 that may be less than or equal to, for instance, inner diameter 703. It is also noted that inner protrusion 1203 may include distal end 1207 that, when annular support structure 209 is supported from pedestal 105, may face and/or abut against an outer surface of focus ring 127, but embodiments are not limited thereto. Further, although upper surface 1001 of annular support structure 209 is shown in FIGS. 2 and 3 as being co-planar with reference plane 317, embodiments are not limited thereto. For example, upper surface 1001 may be arranged axially above or below reference plane 317. In this manner, when annular support structure 209 is supported from pedestal 105, upper surface 1001 may be arranged co-planar with or axially offset from one or more of upper surface 129a of suppressor 129 and upper surface 127a of focus ring 127.

According to some implementations, annular support structure 209 may include a plurality of mating features, such as mating engagement features 1011, configured to interface with bayonet-type engagement features 513 of annular shield rings 129_1, 129_2, . . . , 129_n or bayonet-type engagement features 817 of structure 800. As seen in FIG. 10, annular support structure 209 includes four mating engagement features 1011, two of which are identified, but embodiments are not limited thereto. For instance, annular support structure 209 may include less than four mating engagement features, such as three mating engagement features, or may include greater than four mating engagement features, such as five, six, seven, etc., mating engagement features.

Mating engagement features 1011 may define corresponding protrusions extending from outer surface 1007 in respective radial directions from central axis 1009. As seen in FIG. 12, example mating engagement feature 1011 includes mating (or resting) surface 1209 that, in some implementations, is configured to abut against mating surface 605 of a corresponding bayonet-type engagement feature of suppressor 129 when suppressor 129 is supported by annular support structure 209. For example, mating surface 1209 of one of mating engagement features 1011 may abut against mating surface 605 of one or more of bayonet-type engagement features 513 of annular shield rings 129_1, 129_2, . . . , 129_n or a corresponding mating surface of one of bayonet-type engagement features 817 of structure 800. Mating engagement feature 1011 also includes distal end 1211.

According to some embodiments, annular support structure 209 may be formed of or include a dielectric material, such as a ceramic material, e.g., alumina or aluminum nitride, but embodiments are not limited thereto. In some instances, annular support structure 209 may be formed of a first material, such as a metal or metal alloy (e.g., aluminum or an aluminum alloy), and coated with a second material, such as a dielectric material. Further, the material(s) of annular support structure 209 may be the same as or different from the material(s) of at least one of annular shield rings 129_1, 129_2, . . . , 129_n, structure 800, and/or at least one of dielectric rings 203 and 205.

Although mating engagement features 1011 of annular support structure 209 have been described as corresponding protrusions, embodiments are not limited thereto. For instance, when the engagement features of annular shield rings 129_1, 129_2, . . . , 129_n or structure 800 are alternatively configured, the mating engagement features of annular support structure 209 may be configured to correspondingly interface or function in association therewith. For example, the engagement features of annular shield rings 129_1, 129_2, . . . , 129_n may be provided as through-holes and the engagement features of annular support structure 209 may be provided as through-holes, threaded through-holes, thread bores, press nuts, and/or the like. In this manner, screws, bolts, and/or any other suitable fastening mechanism may be utilized to detachably couple annular shield rings 129_1, 129_2, . . . , 129_n and annular support structure 209 to one another. As another example, when annular shield rings 129_1, 129_2, . . . , 129_n are formed as a monolithic structure, the monolithic structure may have engagement features corresponding to protrusions extending from inner surface 505 of annular shield ring 129_1 similar to how mating engagement features 1011 extend from outer surface 1007 of annular support structure 209. As such, annular support structure 209 may have mating engagement features corresponding to slots configured similarly to slots 601. In yet another example, annular shield ring 129_1 may have engagement features corresponding to protrusions extending from its inner surface 505 similar to how mating engagement features 1011 extend from outer surface 1007 of annular support structure 209. In this manner, annular shield rings 129_2, . . . , 129_n and annular support structure 209 may have mating engagement features corresponding to slots configured similarly to slots 601. In some embodiments, mating engagement features 1011 of annular support structure 209 may be integrated as part of pedestal 105, shroud 207, and/or chamber 103 such that annular support structure 209 may be omitted. It is also contemplated that alternative hardware and/or support structures may be utilized to support suppressor 129 in chamber 103.

Although annular shield rings 129_1, 129_2, . . . , 129_n and annular support structure 209 have been described as being separate structures, it is also contemplated that annular shield rings 129_1, 129_2, . . . , 129_n and annular support structure 209 may be formed as a single a monolithic structure. For instance, one or more additive manufacturing techniques may be utilized to form annular shield rings 129_1, 129_2, . . . , 129_n as a single body (or piece) with an innermost annular shield ring (e.g., annular shield ring 129_n) including inner protrusion 1203 extending circumferentially inwards from its inner surface 505 similar to how inner protrusion 1203 extends circumferentially inwards from inner surface 1005 of annular support structure 209. Further, annular shield rings 129_1, 129_2, . . . , 129_n may not include bayonet-type engagement features 513. Instead, one or more connecting portions may be formed on and/or between annular shield rings 129_1, 129_2, . . . , 129_n as the monolithic structure is being manufactured. For instance, the one or more connecting portions may extend radially between adjacent annular shield rings among annular shield rings 129_1, 129_2, 129_n, but embodiments are not limited thereto.

An example parasitic plasma suppressor assembly between a plurality of annular shield rings (e.g., annular shield rings 129_1, 129_2, . . . , 129_n), annular support structure 209, and retaining structure 1500 that may be supported from pedestal 105 in chamber 103 will now be described in more detail.

### Parasitic Plasma Suppressor Assembly

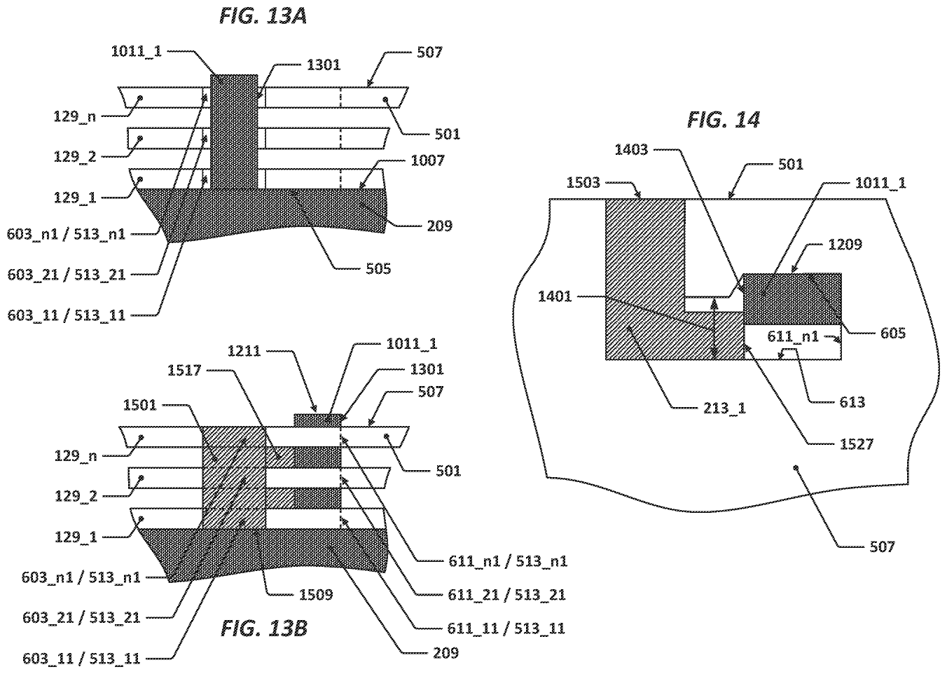

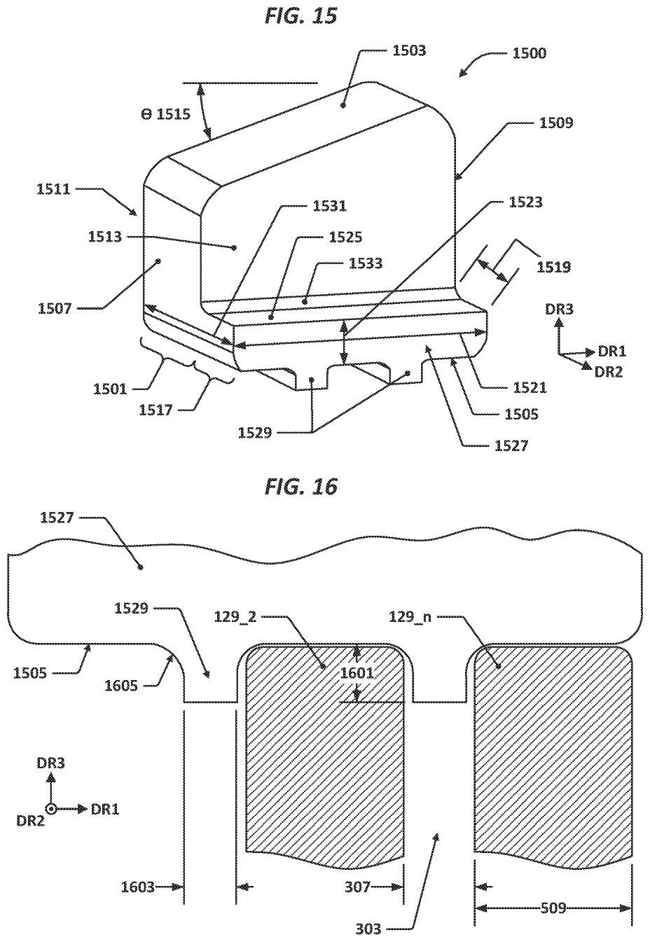

FIG. 13A schematically illustrates a plan view of a portion of a partial assembly between an annular support structure and a plurality of annular shield rings according to some embodiments. FIG. 13B schematically illustrates a plan view of a portion of an assembly between an annular support structure, a plurality of annular shield rings, and a retaining structure according to some embodiments. FIG. 14 schematically illustrates a partial side view of the assembly of FIG. 13B according to some embodiments. FIG. 15 schematically illustrates a perspective view of a retaining structure according to some embodiments. FIG. 16 schematically illustrates a partial side view of a partial assembly between two annular shield rings and a retaining structure according to some embodiments.

Referring to FIGS. 2, 3, 5A, 5B, 6, 7, 10-12, 13A, 13B, and 14-16, a parasitic plasma suppressor assembly may include suppressor 129, annular support structure 209, and one or more retaining structures 213. For descriptive convenience, it will be assumed that suppressor 129 includes annular shield rings 129_1, 129_2, and 129_n, but the following description may be similarly applied in association with structure 800. In some embodiments, to assemble annular shield rings 129_1, 129_2, and 129_n together, annular shield rings 129_1, 129_2, and 129_n may be supported on a level (or substantially level) surface in an arrangement similar to as seen in FIG. 7. Although annular shield rings 129_1, 129_2, and 129_n are shown in FIG. 7 as being concentrically aligned with one another about axis 701, such a configuration need not be the case, but may be achieved through the assembly of suppressor 129, annular support structure 209, and one or more retaining structures 213. That being said, annular shield rings 129_1, 129_2, and 129_n may be arranged such that annular shield ring 129_2 is disposed between an outermost annular shield ring (e.g., annular shield ring 129_n) and an innermost annular shield ring (e.g., annular shield ring 129_1). For descriptive convenience, it will be assumed that annular shield rings 129_1, 129_2, and 129_n are arranged on the surface and concentrically aligned about axis 701.

According to various embodiments, annular shield rings 129_1, 129_2, and 129_n may respectively include a corresponding set of bayonet-type engagement features 513 configured to interface with mating engagement features 1011 of annular support structure 209. For example, a set of bayonet-type engagement features of annular shield ring 129_n may include bayonet-type engagement features 513_n1, 513_n2, 513_n3, and 513_n4 as shown in FIG. 7. Thus, to facilitate assembly with annular support structure 209, annular shield rings 129_1, 129_2, and 129_n may also be arranged on the surface such that openings 603 of corresponding groups of bayonet-type engagement features 513 are radially (or substantially radially) aligned with one another. For instance, bayonet-type engagement features 513_11, 513_21, and 513_n1 of annular shield rings 129_1, 129_2, and 129_n may be part of group 715_1 of bayonet-type engagement features that are radially (or substantially radially) aligned with one another as shown in FIG. 7. Similar arrangements and alignments may exist among bayonet-type engagement features 513 of the other groups of bayonet-type engagement features of annular shield rings 129_1, 129_2, and 129_n, such as groups 715_2, 715_3, and 715_4.

With the above-described arrangement between annular shield rings 129_1, 129_2, and 129_n, mating engagement features 1011 of annular support structure 209 may be inserted into openings 603 of corresponding bayonet-type engagement features 513 of annular shield rings 129_1, 129_2, and 129_n. For example, annular support structure 209 may be arranged over annular shield rings 129_1, 129_2, and 129_n such that central axis 1009 of annular support structure 209 is aligned with axis 701 of annular shield rings 129_1, 129_2, and 129_n. Annular support structure 209 may be translated in the axial direction along axis 701 until, for instance, mating engagement feature 1011_1 of annular support structure 209 is respectively received in openings 603_11, 603_21, and 603_n1 of annular shield rings 129_1, 129_2, and 129_n and abuts against bottom surfaces 613 of corresponding bayonet-type engagement features 513_11, 513_21, and 513_n1, such as shown in FIG. 13A. In some embodiments, when arranged in this partially assembled state, outer surface 1007 of annular support structure 209 may face (and, in some cases, abut against) inner surface 505 of annular shield ring 129_1. Further, distal ends 1211 of mating engagement features 1011 may extend radially beyond outer surface 507 of annular shield ring 129_n, but embodiments are not limited thereto. For example, distal ends 1211 of mating engagement features 1011 may be flush with or radially inset from outer surface 507 of annular shield ring 129_n.

To engage annular support structure 209 with annular shield rings 129_1, 129_2, and 129_n, annular support structure 209 may be rotated about central axis 1009 in a first rotational direction (e.g., a clockwise direction about central axis 1009) until, for example, mating engagement features 1011 abut against distal surfaces 611 of corresponding bayonet-type engagement features 513 of annular shield rings 129_1, 129_2, and 129_n. For example, annular support structure 209 may be rotated about central axis 1009 until, for example, leading surface 1301 of mating engagement feature 1011_1 abuts against distal surfaces 611_11, 611_21, and 611_n1 of bayonet-type engagement features 513_11, 513_21, and 513_n1 of annular shield rings 129_1, 129_2, and 129_n, such as depicted in FIG. 13B.

Once annular support structure 209 is engaged with annular shield rings 129_1, 129_2, and 129_n, mating engagement features 1011 of annular support structure 209 may be at least partially disposed in third portions 601c of bayonet-type engagement features 513 of annular shield rings 129_1, 129_2, and 129_n. To constrain (or at least reduce) relative rotation between annular support structure 209 and annular shield rings 129_1, 129_2, and 129_n, in a second rotational direction opposite the first rotational direction (e.g., in a counterclockwise direction about central axis 1009), one or more retaining structures (or inserts) 213 may be inserted into at least a portion of corresponding spaces in bayonet-type engagement features 513 that are not occupied by mating engagement features 1011. Before describing such an arrangement, an example retaining structure will be described in more detail in association with FIGS. 15 and 16.

Adverting to FIGS. 15 and 16, retaining structure 1500 may include main body portion 1501 having upper surface 1503, lower surface 1505, and a plurality of side surfaces, such as side surfaces 1507, 1509, 1511, and 1513. In some embodiments, side surfaces 1507 and 1509 may oppose one another in first direction DR1, and side surfaces 1511 and 1513 may oppose one another in second direction DR2. Upper surface 1503 may be spaced apart from lower surface 1505 in third direction DR3. Further, upper surface 1503 may slope from side surface 1509 to side surface 1507 at angle 1515, but embodiments are not limited thereto. For instance, upper surface 1503 may not be sloped or may be alternatively configured in any suitable manner.

According to some embodiments, retaining structure 1500 may also include protruded portion 1517 extending from a lower portion of side surface 1513 in second direction DR2 by distance 1519. Protruded portion 1517 may have dimension 1521 in first direction DR1 and dimension 1523 in third direction DR3. In some cases, lower surface 1505 of main body portion 1501 may also correspond to a lower surface of protruded portion 1517. Further, side surfaces 1507 and 1509 of main body portion 1501 may correspond to respective side surfaces of protruded portion 1517. Protruded portion 1517 may also include a plurality of mating surfaces, such as mating surface 1525 and 1527.

In some implementations, retaining structure 1500 includes a plurality of protrusions, e.g., protrusions 1529, extending from lower surface 1505 by dimension 1601 in third direction DR3. Protrusions may also have dimension 1531 in second direction DR2 and dimension 1603 in first direction DR1. According to some embodiments, dimension 1603 may be less than or equal to about maximum dimension 307. Further, protrusions 1529 may have filleted surfaces 1605 interfacing with lower surface 1505, and protruded portion 1517 may have filleted surface 153 interfacing with side surface 1513. Embodiments, however, are not limited thereto.

Referring again to FIGS. 2, 3, 5A, 5B, 6, 7, 10-12, 13A, 13B, and 14-16, one or more retaining structures 213 may be inserted into at least portions of corresponding spaces in bayonet-type engagement features 513 that are not occupied by mating engagement features 1011 when annular support structure 209 is engaged with annular shield rings 129_1, 129_2, and 129_n. For example, retaining structure 2131 may be radially inserted into corresponding first and second portions 601a and 601b of respective bayonet-type engagement features 513_11, 513_21, and 513_n1 of group 7151 of bayonet-type engagement features of annular shield rings 129_1, 129_2, and 129_n. During this insertion process, lower surface 1505 of retaining structure 213_1 may be axially spaced part from corresponding bottom surfaces 613 of bayonet-type engagement features 513_11, 513_21, and 513_n1 until, for instance, side surface 1509 of retaining structure 1500_1 abuts against outer surface 1007 of annular support structure 209. At this point, retaining structure 213_1 may be lowered in the axial direction until lower surface 1505 of retaining structure 213_1 abuts against bottom surfaces 613 of bayonet-type engagement features 513_11, 513_21, and 513_n1. To help facilitate this process, dimension 1401 of second portions 601b of bayonet-type engagement features 513 may be greater than or equal to the sum of the sizes of dimensions 1523 and 1601 of retaining structure 213_1.

As can be appreciated from FIGS. 2, 3, 7, and 16, the lowering of retaining structure 213_1 in the axial direction may enable protrusions 1529 to be respectively inserted in openings 303a and 303b to help maintain the sizing of maximum dimension 307 between adjacent annular shield rings, such as between annular shield rings 129_2 and 129_n. The insertion of respective protrusions 1529 in corresponding openings 303a and 303b may also concentrically (or substantially concentrically) align annular shield rings 129_1, 129_2, and 129_n about axis 701. Further, in this assembled state, mating surface 1527 of retaining structure 213_1 may abut against trailing surface 1403 of mating engagement feature 1011_1, as seen in FIG. 14. This may constrain (or at least reduce) relative rotation between annular support structure 209 and annular shield rings 129_1, 129_2, and 129_n, in the second rotational direction.

In some cases, respective impinging surfaces 609 (see FIG. 6) of corresponding protruded portions 607 of bayonet-type engagement features 513 may also serve to reduce relative rotation between annular support structure 209 and annular shield rings 129_1, 129_2, and 129_n in the second rotational direction. Further, although upper surface 1503 is shown in FIGS. 2, 3, and 14 as being aligned with upper surface 501 of annular shield rings 129_1, 129_2, and 129_n, embodiments are not limited thereto. For instance, upper surface 1503 may extend beyond or may be recessed from one or more of upper surfaces 501 of annular shield rings 129_1, 129_2, and 129_n. In those instances when upper surfaces 501 of annular shield rings 129_1, 129_2, . . . , 129_n are progressively offset from reference plane 317 (an example of which is shown in FIG. 17B), the slopping of upper surface 1503 may generally correspond to the progressive offset of upper surfaces 501.

According to various embodiments, once the parasitic plasma suppressor assembly is assembled, the parasitic plasma suppressor assembly may be arranged over pedestal 105 such that axis 701 is aligned (or substantially aligned) with axis 131. The parasitic plasma suppressor assembly may be lowered in the axial direction along axis 131 until, for instance, mating surface 1205 of annular support structure 209 abuts against at least one of upper surfaces 203a and 205a of dielectric rings 203 and 205. In this supported state, mating surfaces 1209 of mating engagement features 1011 may abut against mating surfaces 605 of bayonet-type engagement features 513. In those instances when distal ends 1211 of mating engagement features 1011 of annular support structure 209 extend beyond outer surface 507 of annular shield ring 129_n, distal ends 1211 may still be spaced apart from an inner surface of chamber 103 or shroud 207, when present.

### Efficacy of System for Parasitic Plasma Suppression

FIGS. 17A and 17B compare parasitic plasma generation in a conventional substrate processing system and a substrate processing system according to some embodiments. To assess the efficacy of an example suppressor, substrate processing systems were set up for PECVD of silicon nitride in association with various power levels utilized to generate plasma in a processing region similar to processing region 121. During plasma generation, digital cameras were used to capture images through viewports into the chambers of the substrate processing systems to visually determine whether parasitic plasma was being generated outside the respective processing regions. The viewports were fitted with metal grids (or perforated screens) to provide shielding from RF radiation. These grids, however, also caused a vignetting effect across the captured images. Even still, it was observed that a conventional substrate processing system (such as shown in FIG. 17A) without a parasitic plasma suppressor allowed parasitic plasma to be generated in at least region 1701 disposed between pedestal 1703 and surrounding chamber components, such as shroud 1705. Dissimilarly, a substrate processing system (such as shown in FIG. 17B) including example parasitic plasma suppressor 1707 suppressed the generation of parasitic plasma in at least region 1701 disposed between pedestal 1703 and surrounding chamber components, such as shroud 1705. To aid in the visualization of components in FIGS. 17A and 17B, pedestal 1703, suppressor 1707, and showerhead 1709 have been generally outlined in white. It was also observed that over a range of 800 watts (W) to 1300 W of input power to pedestal 1703 (or an electrode associated with pedestal 1703) and showerhead 1709 being grounded, the substrate processing system including suppressor 1707 enabled deposition rates of silicon nitride that were about 300 angstroms per minute greater than the deposition rates of silicon nitride associated with the conventional substrate processing system.

### Multi-Station Processing Tool

FIG. 18 schematically illustrates a multi-station processing tool according to some embodiments.

In some implementations, multi-station processing tool 1800 can include an inbound load lock 1803 and an outbound load lock 1805, either or both of which may include a plasma source and/or an ultraviolet (UV) source. Robot 1807, at atmospheric pressure, is configured to move wafers from a cassette loaded through pod 1809 into inbound load lock 1803 via an atmospheric port 1811. Wafer 101 is placed by robot 1807 on pedestal 1813 in inbound load lock 1803, atmospheric port 1811 is closed, and inbound load lock 1803 is pumped down. In instances in which inbound load lock 1803 includes a remote plasma source, wafer 101 may be exposed to a remote plasma treatment in inbound load lock 1803 prior to being introduced into processing chamber 1815. Further, wafer 101 may be heated in inbound load lock 1803 to, for example, remove moisture and/or adsorbed gases. Next, chamber transport port 1817 to processing chamber 1815 is opened, and another robot 1819 places wafer 101 into the reactor on a pedestal of a first station shown in the reactor for processing. While the implementation depicted in FIG. 18 includes load locks, it will be appreciated that, in some implementations, direct entry of wafer 101 into a processing station may be provided.

As seen in FIG. 18, processing chamber 1815 includes four process stations, numbered 1 to 4. Each station has a temperature-controlled pedestal (such as temperature-controlled pedestal 1821 of station 1), and gas line inlets. It will be appreciated that, in some cases, each process station may have different or multiple purposes. For example, in some embodiments, a process station may be switchable between a chemical vapor deposition (CVD) and PECVD process mode. In another example, deposition operations, e.g., PECVD operations, may be performed in one station, while exposure to UV radiation for UV curing may be performed in another station. In some cases, deposition and UV curing may be performed in the same station. Further, although processing chamber 1815 shown as including four stations, embodiments are not limited thereto. For example, processing chamber 1815 may have any suitable number of stations, such as five or more stations, or three or less stations.

As previously mentioned, multi-station processing tool 1800 may include a wafer handling system (e.g., robot 1819 including spider forks 1801) for transferring and/or positioning wafers within processing chamber 1815. In some embodiments, the wafer handling system may transfer wafers between various process stations and/or between a process station and a load lock. It is contemplated, however, that any suitable wafer handling system may be employed, such as, for example, wafer carousels, other wafer handling robots, etc. Further, multi-station processing tool 1800 may include (or otherwise be coupled to) a system controller 1823 employed to control process conditions and hardware states of multi-station processing tool 1800. System controller 1823 may include one or more memory devices 1825, one or more mass storage devices 1827, and one or more processors 1829. Each processor 1829 may include a central processing unit (CPU) or computer, analog, and/or digital input/output connections, stepper motor controller boards, etc.

In some embodiments, system controller 1823 controls each of the activities of multi-station processing tool 1800. For instance, system controller 1823 may execute system control software 1831 stored in mass storage device 1827, loaded into memory device 1825, and executed by processor 1829. Alternatively, control logic may be hard coded in system controller 1823. Application specific integrated circuits (ASIC), programmable logic devices (e.g., field-programmable gate arrays (FPGAs)) and/or the like may be used for these purposes. In the following discussion, wherever “software” or “code” is used, functionally comparable hard coded logic may be used in its place. System control software 1831 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by multi-station processing tool 1800. System control software 1831 may be configured in any suitable way. For example, various process tool component subroutines or control objects may be written to control operation of the process tool components used to carry out various process tool processes. System control software 1831 may be coded in any suitable computer readable programming language.

In some embodiments, system control software 1831 may include input/output control (IOC) sequencing instructions for controlling the various parameters described above. Other computer software and/or programs stored on mass storage device 1827 and/or memory device 1825 associated with system controller 1823 may be employed in some embodiments. Examples of programs or sections of programs for this purpose include a substrate positioning program, a process gas control program, a pressure control program, a heater control program, a cooler control program, and a plasma control program.

A substrate positioning program may include program code for process tool components that are used to load and orientate wafer 101 on pedestal 1821 and to control the spacing between wafer 101 and other parts of multi-station processing tool 1800.

A process gas control program may include code for controlling gas composition (e.g., silicon-containing gases, oxygen-containing gases, nitrogen-containing gases, dilution (or inert) gases, etc.) and flow rates, and optionally for flowing gas into one or more process stations prior to deposition to stabilize the pressure in the process station. A pressure control program may include code for controlling the pressure in the process station by regulating, for example, a throttle valve in an exhaust system of the process station, a gas flow into the process station, and/or the like.

A heater control program may include code for controlling current to a heating unit used to heat a pedestal (e.g., pedestal 1821) and/or a showerhead (e.g., showerhead 113) of processing chamber 1815, and, thereby, to heat wafer 101. Additionally or alternatively, the heater control program may control delivery of a heat transfer gas (such as helium) to a gas distributor, and, thereby, to wafer 101.

A cooling control program may include code for controlling a flow rate of conductive cooling fluid through a cooling unit used to extract heat from a pedestal (e.g., pedestal 1821) and/or a showerhead (e.g., showerhead 113) of processing chamber 1815, and, thereby, transfer such thermal energy to, for instance, a waste heat capturing, storage, recycling, and/or disposing system.

A plasma control program may include code for setting RF power levels applied to the process electrodes in one or more process stations in accordance with various embodiments.

A pressure control program may include code for maintaining pressure in a reaction chamber in accordance with various embodiments.

In some embodiments, a user interface may be provided in association with system controller 1823. The user interface may include a display screen, graphical software displays of the apparatus and/or process conditions, and user input devices, such as pointing devices, keyboards, touch screens, microphones, etc.

In some embodiments, parameters adjusted by system controller 1823 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of system controller 1823 from various process tool sensors. The signals for controlling the process may be output on analog and/or digital output connections of multi-station process tool 1800. Non-limiting examples of process tool sensors that may be monitored include mass flow controllers, pressure sensors (such as manometers), thermocouples, etc. Appropriately programmed feedback and control algorithms may be used with data from the sensors to maintain process conditions.

System controller 1823 may provide program instructions for implementing one or more of the above-described processes. The program instructions may control a variety of process parameters, such as direct current (DC) power level, RF bias power level, pressure, temperature, etc. The instructions may control the parameters to operate deposition of film stacks of a stress compensation layer according to various embodiments.

System controller 1823 will typically include one or more memory devices and one or more processors configured to execute the instructions so that the apparatus will perform a method in accordance with some embodiments. In some instances, machine-readable media containing instructions for controlling process operations in accordance with various embodiments may be coupled to system controller 1823.

In some embodiments, system controller 1823 may be part of a system, which may be part of at least one of the above-described examples. Such systems may include semiconductor processing equipment, including a processing tool or tools, a chamber or chambers, a platform or platforms for processing, and/or specific processing components (e.g., a wafer pedestal, a gas flow system, a thermal management system, etc.). The systems discussed above may be integrated with electronics for controlling their operation before, during, and/or after processing of a semiconductor wafer or substrate. The electronics may be referred to as the “controller,” which may control various components or subparts of the system or systems. For instance, system controller 1823, depending on the processing requirements and/or the type of system, may be programmed to control any of the processes disclosed herein, including the delivery of processing gases, temperature settings (e.g., heating and/or cooling), valve operation, light source control for radiative heating, pressure settings, vacuum settings, power settings, RF generator settings, RF matching circuit settings, frequency settings, flow rate settings, fluid delivery settings, positional and operational settings, wafer transfers into and out of a tool or chamber and other transfer tools and/or load locks connected to or interfaced with a specific system. In this manner, system controller 1823 may be configured to control, among other systems, the various actuators and motors of a backside wafer processing system.

Broadly speaking, system controller 1823 may be defined as electronics having various integrated circuits, logic, memory, and/or software that receive instructions, issue instructions, control operation, enable cleaning operations, enable endpoint measurements, and/or the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to system controller 1823 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon oxide, surfaces, circuits, dies of a wafer, etc.

System controller 1823, in some implementations, may be a part of or coupled to a computer that is integrated with, coupled to the system, otherwise networked to the system, or a combination thereof. For example, system controller 1823 may be in the “cloud” or all or a part of a fab host computer system, which can allow for remote access of wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It is to be understood that the parameters may be specific to the type of process to be performed and the type of tool that the controller is configured to interface with or control. Thus, as described above, system controller 1823 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and/or any other semiconductor processing system that may be associated or used in the fabrication and/or manufacturing of semiconductor wafers.

As noted above, depending on the process step or steps to be performed by the tool, system controller 1823 might communicate with one or more of other tool circuits or modules, other tool components, cluster tools, other tool interfaces, adjacent tools, neighboring tools, tools located throughout a factory, a main computer, another controller, and/or tools used in material transport that bring containers of wafers to and from tool locations and/or load ports in a semiconductor manufacturing factory.

### ADDITIONAL AND/OR ALTERNATIVE EMBODIMENTS

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in itself, as necessarily encompassing a plurality of items—it is to be understood that a set or a subset can encompass only one member or multiple members (unless the context indicates otherwise). The terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. Accordingly, the term “substantially” as used herein, unless otherwise specified, means within 5% of a referenced value. For example, substantially perpendicular means within ±5% of parallel.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. When an embodiment may be implemented differently, a specific process order may be performed differently from the described order. For example, two consecutively described processes may be performed substantially at the same time or performed in an order opposite to the described order.

When an element, such as a layer, is referred to as being “on,” “connected to,” or “coupled to” another element, it may be directly on, directly connected to, or directly coupled to the other element or at least one intervening element may be present. When, however, an element is referred to as being “directly on,” “directly connected to,” or “directly coupled to” another element, there are no intervening elements present. Other terms and/or phrases if used herein to describe a relationship between elements should be interpreted in a like fashion, such as “between” versus “directly between,” “adjacent” versus “directly adjacent,” “on” versus “directly on,” etc. Further, the term “connected” may refer to physical, electrical, and/or fluid connection. To this end, for the purposes of this disclosure, the phrase “fluidically connected” is used with respect to volumes, plenums, holes, etc., that may be connected to one another, either directly or via one or more intervening components or volumes, to form a fluidic connection, similar to how the phrase “electrically connected” is used with respect to components that are connected to form an electric connection. The phrase “fluidically interposed,” if used, may be used to refer to a component, volume, plenum, hole, etc., that is fluidically connected with at least two other components, volumes, plenums, holes, etc., such that fluid flowing from one of those other components, volumes, plenums, holes etc., to the other or another of those components, volumes, plenums, holes, etc., would first flow through the “fluidically interposed” component before reaching that other or another of those components, volumes, plenums, holes, etc. For example, if a pump is fluidically interposed between a reservoir and an outlet, fluid flowing from the reservoir to the outlet would first flow through the pump before reaching the outlet. The phrase “fluidically adjacent,” if used, refers to placement of a fluidic element relative to another fluidic element such that no potential structures fluidically are interposed between the two elements that might potentially interrupt fluid flow between the two fluidic elements. For example, in a flow path having a first valve, a second valve, and a third valve arranged sequentially therealong, the first valve would be fluidically adjacent to the second valve, the second valve fluidically adjacent to both the first and third valves, and the third valve fluidically adjacent to the second valve.

For the purposes of this disclosure, “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. As used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.” Further, the use, if any, of ordinal indicators, such as (a), (b), (c), . . . , or (1), (2), (3), . . . , or the like, in this disclosure and accompanying claims, is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated), unless indicated otherwise. For example, if step (ii) involves the handling of an element that is created in step (i), then step (ii) may be viewed as happening at some point after step (i). In a similar manner, if step (i) involves the handling of an element that is created in step (ii), the reverse is to be understood.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The term “between,” as used herein and when used with a range of values, is to be understood, unless otherwise indicated, as being inclusive of the start and end values of that range. For example, between 1 and 5 is to be understood as inclusive of the numbers 1, 2, 3, 4, and 5, not just the numbers 2, 3, and 4.

As used herein, the phrase “operatively connected” is to be understood as referring to a state in which two components and/or systems are connected, either directly or indirectly, such that, for example, at least one component or system can control the other. For instance, a controller may be described as being operatively connected with (or to) a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely will not supply such power directly to the resistive heating unit due to the current(s) involved, but it is to be understood that the controller is nonetheless operatively connected with the resistive heating unit.

As used herein, the singular forms, “a,” “an,” and “the” are intended to include the plural forms as well, unless the context clearly indicates otherwise. It is also to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in itself, as necessarily encompassing a plurality of items—it is to be understood that a set or a subset can encompass only one member or multiple members (unless the context indicates otherwise). In addition, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described herein with reference to sectional views, isometric views, perspective views, plan views, and/or exploded illustrations that are schematic depictions of idealized embodiments and/or intermediate structures. As such, variations from the shapes of the illustrations as a result of, for example, manufacturing techniques and/or tolerances, are to be expected. Thus, embodiments disclosed herein should not be construed as limited to the particular illustrated shapes of regions, but are to include deviations in shapes that result from, for instance, manufacturing. To this end, regions illustrated in the drawings may be schematic in nature and shapes of these regions may not reflect the actual shapes of regions of a device, and, as such, are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and are not to be interpreted in an idealized or overly formal sense, unless expressly so defined herein.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the inventive concepts. Further, the blocks, units, and/or modules of some embodiments may be physically combined into more complex blocks, units, and/or modules without departing from the teachings of the disclosure.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered as illustrative and not as restrictive, and embodiments are not to be limited to the details given herein.

It is to be further understood that the above disclosure, although focusing on a particular example implementation or implementations, is not limited to only the discussed example, but may also apply to similar variants and mechanisms as well, and such similar variants and mechanisms are also considered to be within the scope of this disclosure. For the avoidance of any doubt, it is also to be understood that the above disclosure is at least directed to the following numbered implementations, as well as to other implementations that are evident from the above disclosure.
Implementation 1: An apparatus configured to mitigate parasitic plasma generation in association with a plasma-enhanced process, the apparatus including an annular shield structure. The annular shield structure includes a first inner surface, a first outer surface, a first upper surface, a first lower surface, and a plurality of openings. The first outer surface opposes the first inner surface in a radial direction. The first upper surface extends between the first inner surface and the first outer surface. The first lower surface extends between the first inner surface and the first outer surface. The first lower surface opposes the first upper surface in an axial direction transverse to the radial direction. The openings longitudinally extend between the first upper surface and the first lower surface. The openings respectively include a maximum dimension in a plane perpendicular to the axial direction that is less than or equal to about twice a plasma sheath thickness associated with the plasma-enhanced process.
Implementation 2: The apparatus of implementation 1, in which the maximum dimension extends in the radial direction.
Implementation 3: The apparatus of either implementation 1 or implementation 2, in which the openings respectively further include a minimum dimension in the axial direction or a direction transverse to the axial direction.
Implementation 4: The apparatus of any one of implementations 1 to 3, in which the annular shield structure includes a plurality of annular shield rings spaced apart from one another by the maximum dimension in the radial direction such that the openings are defined by the spacing between the annular shield rings.
Implementation 5: The apparatus of any one of implementations 1 to 3, in which the annular shield structure is formed as a unitary body, and the openings are defined as through-holes extending through the unitary body.
Implementation 6: The apparatus of any one of implementations 1 to 3, further including an annular support structure. The annular support structure includes a second inner surface, and a second outer surface between the first inner surface and the second inner surface in the radial direction such that the annular shield structure surrounds the annular support structure. The annular shield structure and the annular support structure are detachably coupled to one another.
Implementation 7: The apparatus of implementation 6, in which the annular shield structure and the annular support structure are detachably coupled to one another via a bayonet-type engagement.
Implementation 8: The apparatus of implementation 7, in which the bayonet-type engagement includes a plurality of protrusions and a plurality of slots. The protrusions extend radially from one of the first inner surface and the second outer surface. The slots are defined in the other of the first inner surface and the second outer surface. The slots are respectively configured to: receive, in a first slot portion, a corresponding protrusion among the protrusions in response to relative translation between the annular shield structure and the annular support structure in the axial direction; and receive, in a second slot portion communicatively coupled to the first slot portion, the corresponding protrusion in response to relative rotation between the annular shield structure and the annular support structure in a first rotational direction about an axis extending in the axial direction.
Implementation 9: The apparatus of implementation 8, in which the plurality of protrusions includes at least three protrusions.
Implementation 10: The apparatus of implementation 8, in which the plurality of protrusions includes at least four protrusions.
Implementation 11: The apparatus of any one of implementations 8 to 10, in which the annular shield structure includes a plurality of annular shield rings spaced apart from one another by the maximum dimension in the radial direction such that the openings are defined by the spacing between the annular shield rings, and the annular shield rings respectively include a corresponding set of the plurality of slots.
Implementation 12: The apparatus of implementation 11, in which upper surfaces of the respective annular shield rings are offset from one another in the axial direction.
Implementation 13: The apparatus of implementation 12, in which the upper surfaces of the annular shield rings are offset such that the upper surfaces of the annular shield rings increase in distance from a reference plane with increasing distance from the first inner surface, the reference plane including an upper surface among the upper surfaces that is closest to the first inner surface.
Implementation 14: The apparatus of any one of implementations 11 to 13, in which, in an engaged state of the bayonet-type engagement, corresponding slots of the corresponding sets are configured to receive a same corresponding protrusion among the plurality of protrusions.
Implementation 15: The apparatus of any one of implementations 11 to 14, further including one or more retaining structures configured to constrain relative rotation between the annular shield structure and the annular support structure in a second rotational direction about the axis, the second rotational direction being opposite the first rotational direction.
Implementation 16: The apparatus of implementation 15, in which at least one slot among the slots is further configured to receive a retaining structure among the one or more retaining structures in the first slot portion of the at least one slot and a third slot portion of the at least one slot in response to relative translation between the retaining structure and the at least one slot in the radial direction, the third slot portion of the at least one slot being communicatively coupled between the first slot portion of the at least one slot and the second slot portion of the at least one slot. In an engaged state of the annular shield structure and the annular support structure and an engaged state of the retaining structure and the at least one slot, the retaining structure is configured to retain the corresponding protrusion in the second slot portion of the at least one slot.
Implementation 17: The apparatus of implementation 16, in which the retraining structure includes a main body portion, a first protrusion extending from a first sidewall of the main body portion, and a plurality of second protrusions extending from a lower surface of the main body portion, the first protrusion, or the main body portion and the first protrusion. In the engaged state of the retaining structure and the at least one slot the main body is disposed in the first slot portion of the at least one slot, the first protrusion is disposed in one or both of the second slot portion of the at least one slot and the third slot portion of the at least one slot, and the second protrusions are disposed in respective openings among the openings in the annular shield structure.
Implementation 18: The apparatus of any one of implementations 8 to 10, further including one or more retaining structures. At least one slot among the slots is further configured to receive a retaining structure among the one or more retaining structures in the first slot portion of the at least one slot and a third slot portion of the at least one slot in response to relative translation between the retaining structure and the at least one slot in the radial direction. The third slot portion of the at least one slot connects the first slot portion of the at least one slot to the second slot portion of the at least one slot. In an engaged state of the annular shield structure and the annular support structure and an engaged state of the retaining structure and the at least one slot, the retaining structure is configured to retain the corresponding protrusion in the second slot portion of the at least one slot and constrain relative rotation between the annular shield structure and the annular support structure in a second rotational direction about the axis. The second rotational direction is opposite the first rotational direction.
Implementation 19: The apparatus of any one of implementations 6 to 18, in which the annular support structure further includes at least one inner protrusion extending from the second inner surface towards a central axis of the annular support structure. The central axis extends in the axial direction. The at least one inner protrusion includes a third upper surface, and a third lower surface opposing the third upper surface in the axial direction.
Implementation 20: The apparatus of implementation 19, in which the at least one inner protrusion circumferentially extends about at least part of a periphery of the annular support structure.
Implementation 21: The apparatus of either implementation 19 or implementation 20, further including a process chamber including at least one sidewall, and a pedestal supported within the process chamber. The pedestal includes an outer boundary surface. In the radial direction, the annular shield structure is disposed between the outer boundary surface of the pedestal and the at least one sidewall.
Implementation 22: The apparatus of implementation 21, further including a showerhead supported in the process chamber such that the showerhead faces the pedestal in the axial direction. The showerhead is configured to distribute one or more process gases in a region overlying the pedestal.
Implementation 23: The apparatus of either implementation 21 or implementation 22, further including at least one dielectric ring surrounding the outer boundary surface of the pedestal. The at least one dielectric ring includes a fourth inner surface facing the outer boundary surface of the pedestal in the radial direction, a fourth outer surface opposing the fourth inner surface in the radial direction, a fourth upper surface extending between the fourth inner surface and the fourth outer surface, and a fourth lower surface extending between the fourth inner surface and the fourth outer surface. The fourth lower surface opposes the fourth upper surface in the axial direction. In the radial direction, the annular shield structure is disposed between the at least one dielectric ring and the at least one sidewall.
Implementation 24: The apparatus of implementation 23, in which the first inner surface is spaced apart from the fourth outer surface by a dimension in the plane perpendicular to the axial direction that is less than or equal to about the plasma sheath thickness associated with the plasma-enhanced process.
Implementation 25: The apparatus of implementation 23 or implementation 24, further including a focus ring disposed on an outer peripheral portion of an upper surface of the pedestal. The focus ring includes a fifth inner surface, a fifth outer surface opposing the fifth inner surface in the radial direction, a fifth upper surface extending between the fifth inner surface and the fifth outer surface, and a fifth lower surface extending between the fifth inner surface and the fifth outer surface. The fifth lower surface opposes the fifth upper surface in the axial direction. In a plan view, at least a portion of the fourth upper surface is adjacent to the fifth upper surface in the radial direction.
Implementation 26: The apparatus of implementation 25, in which the first upper surface is disposed below a reference plane including the fifth upper surface.
Implementation 27: The apparatus of either implementation 25 or implementation 26, in which the fourth upper surface is disposed at or below a reference plane including the fifth lower surface.
Implementation 28: The apparatus of any one of implementations 25 to 27, in which the third lower surface abuts against the fourth upper surface.
Implementation 29: The apparatus of any one of implementations 25 to 28, in which the second inner surface abuts against the fourth outer surface.
Implementation 30: The apparatus of any one of implementations 21 to 29, in which the first outer surface is spaced apart from the at least one sidewall.
Implementation 31: The apparatus of implementation 30, in which the plurality of protrusions extends radially from the second outer surface, an outermost boundary surface of at least one of the plurality of protrusions is disposed closer to the at least one sidewall than the first outer surface, and the outermost boundary surface of the at least one protrusion is spaced apart from the at least one sidewall.
Implementation 32: The apparatus of implementation 31, further including a shroud lining an interior surface of the at least one sidewall. In the radial direction, the annular shield structure is disposed between the outer boundary surface of the pedestal and the shroud, and the outermost boundary surface of the at least one protrusion is spaced apart from the shroud.
Implementation 33: The apparatus of any one of implementations 21 to 30, further including a shroud lining an interior surface of the at least one sidewall. In the radial direction, the annular shield structure is disposed between the outer boundary surface of the pedestal and the shroud.
Implementation 34: The apparatus of either implementation 32 or implementation 33, in which the shroud includes aluminum.
Implementation 35: The apparatus of any one of implementations implementation 21 to 34, in which the process chamber includes an exhaust gas port configured to evacuate gas in association with the plasma-enhanced process. The gas including by-product gas, unreacted process gas, or by-product gas and unreacted process gas. The openings are configured to permit the gas to flow from a first region overlying the pedestal to the exhaust gas port via a second region adjacent to the first region, the second region being spaced apart from the pedestal in the radial direction; and to suppress generation of plasma in the second region.
Implementation 36: The apparatus of any one of implementations 1 to 35, in which, in association with the plasma-enhanced process, the openings are further configured to quench a flow of one or more energetic species therethrough.
Implementation 37: The apparatus of any one of implementations 21 to 35, in which the pedestal is configured to support a substrate in the process chamber, the substrate including a maximum dimension in a direction perpendicular to the axial direction. A maximum dimension between opposing portions of the first inner surface in the direction perpendicular to the axial direction is greater than the maximum dimension of the substrate.
Implementation 38: The apparatus of any one of implementations 6 to 37, in which the first inner surface abuts against the second outer surface.
Implementation 39: The apparatus of any one of implementations 6 to 38, in which a maximum dimension of the annular shield structure in the axial direction is greater than a maximum dimension of the annular support structure in the axial direction.
Implementation 40: The apparatus of any one of implementations 1 to 39, in which the annular shield structure includes a ceramic material.
Implementation 41: The apparatus of any one of implementations 1 to 40, in which the annular support structure includes a ceramic material.

1. An apparatus configured to mitigate parasitic plasma generation in association with a plasma-enhanced process, the apparatus comprising:
an annular shield structure comprising:
a first inner surface;
a first outer surface opposing the first inner surface in a radial direction;
a first upper surface extending between the first inner surface and the first outer surface;
a first lower surface extending between the first inner surface and the first outer surface, the first lower surface opposing the first upper surface in an axial direction transverse to the radial direction; and
a plurality of openings longitudinally extending between the first upper surface and the first lower surface,
wherein the openings respectively comprise a maximum dimension in a plane perpendicular to the axial direction that is less than or equal to about twice a plasma sheath thickness associated with the plasma-enhanced process.

2. The apparatus of claim 1, wherein:
the maximum dimension extends in the radial direction; and
the openings respectively further comprise a minimum dimension in the axial direction or a direction transverse to the axial direction.

3. The apparatus of claim 1, wherein the annular shield structure comprises a plurality of annular shield rings spaced apart from one another by the maximum dimension in the radial direction such that the openings are defined by the spacing between the annular shield rings.

4. The apparatus of claim 1, further comprising:
an annular support structure comprising:
a second inner surface; and
a second outer surface between the first inner surface and the second inner surface in the radial direction such that the annular shield structure surrounds the annular support structure,
wherein the annular shield structure and the annular support structure are detachably coupled to one another.

5. The apparatus of claim 4, wherein the annular shield structure and the annular support structure are detachably coupled to one another via a bayonet-type engagement.

6. The apparatus of claim 5, wherein the bayonet-type engagement comprises:
a plurality of protrusions extending radially from one of the first inner surface and the second outer surface; and
a plurality of slots defined in an other one of the first inner surface and the second outer surface, the slots being respectively configured to:
receive, in a first slot portion, a corresponding protrusion among the protrusions in response to relative translation between the annular shield structure and the annular support structure in the axial direction; and
receive, in a second slot portion communicatively coupled to the first slot portion, the corresponding protrusion in response to relative rotation between the annular shield structure and the annular support structure in a first rotational direction about an axis extending in the axial direction.

7. The apparatus of claim 6, wherein the plurality of protrusions includes at least three protrusions.

8. The apparatus of claim 6, wherein:
the annular shield structure comprises a plurality of annular shield rings spaced apart from one another by the maximum dimension in the radial direction such that the openings are defined by the spacing between the annular shield rings; and
the annular shield rings respectively comprise a corresponding set of the plurality of slots.

9. The apparatus of claim 8, wherein upper surfaces of the annular shield rings are offset from one another in the axial direction such that the upper surfaces of the annular shield rings increase in distance from a reference plane with increasing distance from the first inner surface, the reference plane including an upper surface among the upper surfaces that is closest to the first inner surface.

10. The apparatus of claim 8, wherein, in an engaged state of the bayonet-type engagement, corresponding slots are configured to receive a same corresponding protrusion among the plurality of protrusions.

11. The apparatus of claim 8, further comprising:
one or more retaining structures configured to constrain relative rotation between the annular shield structure and the annular support structure in a second rotational direction about the axis, the second rotational direction being opposite the first rotational direction.

12. The apparatus of claim 11, wherein:
at least one slot among the slots is further configured to receive a retaining structure among the one or more retaining structures in the first slot portion of the at least one slot and a third slot portion of the at least one slot in response to relative translation between the retaining structure and the at least one slot in the radial direction, the third slot portion of the at least one slot being communicatively coupled between the first slot portion of the at least one slot and the second slot portion of the at least one slot; and
in an engaged state of the annular shield structure and the annular support structure and an engaged state of the retaining structure and the at least one slot, the retaining structure is configured to retain the corresponding protrusion in the second slot portion of the at least one slot.

13. The apparatus of claim 12, wherein:
the retaining structure of the one or more retaining structures comprises:
a main body portion;
a first protrusion extending from a first sidewall of the main body portion; and
a plurality of second protrusions extending from a lower surface of the main body portion, the first protrusion, or the main body portion and the first protrusion; and
in the engaged state of the retaining structure and the at least one slot:
the main body portion is disposed in the first slot portion of the at least one slot;
the first protrusion is disposed in one or both of the second slot portion of the at least one slot and the third slot portion of the at least one slot; and
the second protrusions are disposed in respective openings among the openings in the annular shield structure.

14. The apparatus of claim 6, further comprising:
one or more retaining structures,
wherein:
at least one slot among the slots is further configured to receive a retaining structure among the one or more retaining structures in the first slot portion of the at least one slot and a third slot portion of the at least one slot in response to relative translation between the retaining structure and the at least one slot in the radial direction, the third slot portion of the at least one slot connecting the first slot portion of the at least one slot to the second slot portion of the at least one slot;
in an engaged state of the annular shield structure and the annular support structure and an engaged state of the retaining structure and the at least one slot, the retaining structure is configured to retain the corresponding protrusion in the second slot portion of the at least one slot and constrain relative rotation between the annular shield structure and the annular support structure in a second rotational direction about the axis; and
the second rotational direction is opposite the first rotational direction.

15. The apparatus gf claim 4, wherein:
the annular support structure further comprises at least one inner protrusion extending from the second inner surface towards a central axis of the annular support structure, the central axis extending in the axial direction;
the at least one inner protrusion comprises:
a third upper surface; and
a third lower surface opposing the third upper surface in the axial direction; and
the at least one inner protrusion circumferentially extends about at least part of a periphery of the annular support structure.

16. The apparatus of claim 15, further comprising:
a process chamber comprising at least one sidewall;
a pedestal supported within the process chamber, the pedestal comprising an outer boundary surface; and
a showerhead supported in the process chamber such that the showerhead faces the pedestal in the axial direction, the showerhead being configured to distribute one or more process gases in a region overlying the pedestal,
wherein, in the radial direction, the annular shield structure is disposed between the outer boundary surface of the pedestal and the at least one sidewall.

17. The apparatus of claim 16, further comprising:
at least one dielectric ring surrounding the outer boundary surface of the pedestal, the at least one dielectric ring comprising:
a fourth inner surface facing the outer boundary surface of the pedestal in the radial direction;
a fourth outer surface opposing the fourth inner surface in the radial direction;
a fourth upper surface extending between the fourth inner surface and the fourth outer surface; and
a fourth lower surface extending between the fourth inner surface and the fourth outer surface, the fourth lower surface opposing the fourth upper surface in the axial direction,
wherein:
in the radial direction, the annular shield structure is disposed between the at least one dielectric ring and the at least one sidewall; and
the first inner surface is spaced apart from the fourth outer surface by a dimension in the plane perpendicular to the axial direction that is less than or equal to about the plasma sheath thickness associated with the plasma-enhanced process.

18. The apparatus of claim 17, further comprising:
a focus ring disposed on an outer peripheral portion of an upper surface of the pedestal, the focus ring comprising:
a fifth inner surface;
a fifth outer surface opposing the fifth inner surface in the radial direction;
a fifth upper surface extending between the fifth inner surface and the fifth outer surface; and
a fifth lower surface extending between the fifth inner surface and the fifth outer surface, the fifth lower surface opposing the fifth upper surface in the axial direction,
wherein:
in a plan view, at least a portion of the fourth upper surface is adjacent to the fifth upper surface in the radial direction;
the first upper surface is disposed below a reference plane including the fifth upper surface;
the fourth upper surface is disposed at or below a reference plane including the fifth lower surface;
the third lower surface abuts the fourth upper surface;
the second inner surface abuts the fourth outer surface; and
the first outer surface is spaced apart from the at least one sidewall.

19. The apparatus of claim 18, wherein:
the plurality of protrusions extends radially from the second outer surface;
an outermost boundary surface of at least one protrusion of the plurality of protrusions is disposed closer to the at least one sidewall than the first outer surface; and
the outermost boundary surface of the at least one protrusion is spaced apart from the at least one sidewall.

20. The apparatus of claim 19, further comprising:
a shroud lining an interior surface of the at least one sidewall,
wherein:
in the radial direction, the annular shield structure is disposed between the outer boundary surface of the pedestal and the shroud; and
the outermost boundary surface of the at least one protrusion is spaced apart from the shroud.
